(19) United States
(12) Patent Application Publication
(10) Pub. No.: US 2019/0386064 A1
(43) Pub. Date: Dec. 19, 2019

(54) DETECTOR FOR AN OPTICAL DETECTION OF AT LEAST ONE OBJECT

(71) Applicant: trinamiX GmbH, Ludwigshafen am Rhein (DE)

(72) Inventors: Sebastian VALOUCH, Ludwigshafen (DE); Wilfried HERMES, Ludwigshafen (DE); Ingmar BRUDER, Ludwigshafen (DE); Robert SEND, Ludwigshafen (DE); Christoph LUNGENSCHMIED, Ludwigshafen (DE)

(73) Assignee: trinamiX GmbH, Ludwigshafen am Rhein (DE)

(21) Appl. No.: 16/478,907

(22) PCT Filed: Feb. 7, 2018
(86) PCT No.: PCT/EP2018/053057

§ 371 Date: Jul. 18, 2019

(30) Foreign Application Priority Data
Feb. 8, 2017 (EP) 17155171.6

(51) Int. Cl. H01L 27/30; G01S 17/46; H01L 31/0224; H01L 51/44; H01L 27/146

(52) U.S. Cl. CPC H01L 27/307; G01S 17/46; G01S 7/4816; H01L 51/442; H01L 27/14601; H01L 31/022466

(57) ABSTRACT

Disclosed herein is a detector including (i) a transversal optical sensor adapted to determine a transversal position of a light beam traveling from the object to the detector, wherein the transversal optical sensor has a photosensitive layer embedded between at least two conductive layers such that at least one of the conductive layers contains an at least partially transparent graphene layer on an at least partially transparent substrate, and wherein the transversal optical sensor generates a transversal sensor signal indicative of the transversal position of the light beam in the photosensitive layer, and (ii) an evaluation device designed to generate at least one item of information on a transversal position of the object by evaluating the at least one transversal sensor signal.

### FIELD OF THE INVENTION

The invention relates to a detector for an optical detection of at least one object, in particular, for determining a position of at least one object, specifically a lateral position of the at least one object. Furthermore, the invention relates to a human-machine interface, an entertainment device, a tracking system, a scanning system, and a camera. Further, the invention relates to a method for optical detection of at least one object and to various uses of the detector. Such devices, methods and uses can be employed for example in various areas of daily life, gaming, traffic technology, mapping of spaces, production technology, security technology, medical technology or in the sciences. However, further applications are possible.

### Prior Art

A large number of optical sensors and photosensitive devices are known from the prior art. While photosensitive devices are generally used to convert electromagnetic radiation, for example, ultra-violet, visible or infrared light, into electrical signals or electrical energy, optical detectors are generally used for picking up image information, such as a position of a radiating or illuminated object, and/or for detecting at least one optical parameter, for example, a brightness.

Various detectors for optically detecting a lateral position of at least one object are known on the basis of optical sensors. In general, image sensors based on CMOS or CCD technology can be used for analyzing the position of a light spot. However, in order to enhance a lateral resolution by reduced costs position-sensitive sensors are used increasingly. Herein, the position-sensitive diodes utilize that a generated photocurrent may exhibit a lateral division. In a way as known from the state of the art, the term “position sensitive detector” or “PSD”, thus, usually refers to an optical detector that may employ silicon based diodes for determining a position of a focus of an incident light beam. Consequently, a light spot on a surface area of the PSD may generate electrical signals corresponding to a position of the light spot on the surface area, wherein the position of the light spot may, particularly, be determined from a relationship between at least two electrical signals. Based on intransparent optical properties of the silicon material as employed in this kind of PSD, transversal optical sensors which utilize position-sensitive silicon diodes are, however, intransparent optical sensors, an observation that may be capable of severely limiting their range of applicability.

In U.S. Pat. No. 6,995,445 and US 2007/0176165 A1, a position sensitive organic detector is disclosed. Therein, a resistive bottom electrode, is used which is electrically contacted by using at least two electrical contacts. By forming a current ratio of the currents from the electric contacts, a position of a light spot on the organic detector may be detected.

WO 2014/097181 A1, the full content of which is herewith included by reference, discloses a method and a detector for determining a position of at least one object, by using at least one longitudinal optical sensor and at least one transversal optical sensor. Specifically, the use of sensor stacks is disclosed, in order to determine both a longitudinal position and at least one lateral position of the object with a high degree of accuracy and without ambiguity. Herein, the transversal optical sensor is a photo detector having at least one first electrode, at least one second electrode and at least one photovoltaic material, wherein the photovoltaic material is embedded in between the first electrode and the second electrode. For this purpose, the transversal optical sensor is or comprises one or more dye-sensitized organic solar cells (DSCs, also referred to as dye solar cells), such as one or more solid dye-sensitized organic solar cells (s-DSCs). However, known transversal optical sensors that employ these kinds of materials can, in general, only be used for the optical detection of wavelengths below 1000 nm. Due to their inefficiency for wavelengths above 1000 nm an upconversion material is usually required. As a result, such transversal optical sensors may be inefficient enough to be used for an optical detection within the infrared spectral range. Herein, graphene may be employed as alternative to a metal electrode as one of the split electrodes which are used for reading out the information required for determining the transversal position of the light beam within the sensor area. Further, a human-machine interface, an entertainment device, a tracking system, and a camera are disclosed, each comprising at least one such detector for determining a position of at least one object.

WO 2016/120392 A1, the full content of which is herewith included by reference, discloses a transversal optical sensor adapted to determine a transversal position of at least one light beam traveling from the object to the detector. Herein, the transversal optical sensor may comprise a layer of the photoconductive material, preferably an inorganic photoconductive material, wherein the layer of the photoconductive material may comprise a composition selected from a homogeneous, a crystalline, a polycrystalline, a microcrystalline, a nanocrystalline and/or an amorphous phase. Herein, the photoconductive material may, preferably, be selected from the group comprising lead sulfide (PbS), lead selenide (PbSe), lead telluride (PbTe), cadmium telluride (CdTe), indium phosphide (InP), cadmium sulfide (CdS), cadmium selenide (CdSe), indium antimonide (InSb), mercury cadmium telluride (HgCdTe; MCT), copper indium sulfide (CIS), copper indium gallium selenide (CIGS), zinc sulfide (ZnS), zinc selenide (ZnSe), a perovskite structure materials ABC₃, wherein A denotes an alkaline metal or an organic cation, B=Pb, Sn, or Cu, and C a halide, and copper zinc tin sulfide (CZTS). Further, solid solutions and/or doped variants of the mentioned compounds or of other compounds of this kind may also be feasible. Preferably, the layer of the photoconductive material may be embedded in between two layers of a transparent conducting oxide, preferably comprising indium tin oxide (ITO), fluorine doped tin oxide (FTO), or magnesium oxide (MgO), wherein one of the two layers may be replaced by metal nanowires, such as by Ag nanowires, in particular depending on the desired transparent spectral range. Further, graphene may be employed herein as alternative to a metal electrode as one of the split electrodes which are used for reading out the information required for determining the transversal position of the light beam within the sensor area.

Further, WO 2017/182432 A1, the full content of all of which is herewith included by reference, discloses a detector for an optical detection of at least one object comprising at least one transversal optical sensor adapted to determine a transversal position of a light beam traveling from the object to the detector, wherein the transversal position is a position in at least one dimension perpendicular to an optical axis of the detector, wherein the transversal optical sensor has at least one photovoltaic layer embedded between at least two conductive layers, wherein the photovoltaic layer comprises a plurality of quantum dots, wherein at least one of the conductive layers is at least partially transparent allowing the light beam to travel to the photovoltaic layer. Further, the transversal optical sensor has at least one split electrode located at one of the conductive layers, wherein the split electrode has at least two partial electrodes adapted to generate at least one transversal sensor signal indicative of the transversal position of the light beam in the photovoltaic layer. Further, the transversal optical sensor has at least one evaluation device being designed to generate at least one item of information on a transversal position of the object by evaluating the at least one transversal sensor signal.

N.-E. Weber, A. Binder, M. Kettner, S. Hirth, R. T. Weitz, and Z. Tomovic, Metal-free synthesis of nanocrystalline graphene on insulating substrates by carbon dioxide-assisted chemical vapor deposition, Carbon 112, pp. 201-207, 2017, refers to the scalable, low-cost fabrication of high quality graphene. A method to synthesize uniform and large area graphene films directly on various high-temperature resistant insulating substrates such as SiO₂/Si, Al₂O₃ and quartz glass by low pressure chemical vapor deposition (LP-CVD) using a mild oxidant (CO₂) and a carbon source (CH₄), without the aid of any metallic species or catalysts, is reported. The resulting films are uniform and homogeneous on a large scale and comprise nanocrystalline graphene domains. The obtained graphene films show excellent electrical transport properties with high charge carrier mobilities up to 720 cm²/(Vs).

Further, US 2012/328906 A1 discloses a method of manufacturing graphene, a transparent electrode and an active layer including the graphene as well as a display, an electronic device, an optoelectronic device, a solar cell, and a dye-sensitized solar cell including the transparent graphene electrode and the active layer. In particular, D4 discloses a graphene sheet as a transparent electrode which may be used for a liquid crystal display, an electronic paper display, an organic optoelectronic device, a battery and a solar cell.

Further, US 2013/320302 A1 addresses an optical detector which comprises graphene and a conductive polymer, e.g., a thin layer of PEDOT:PSS inserted before the deposition of the electron donor material in order to favor an Ohmic contact at the junction. Herein, the application of PEDOT:PSS on a surface of the graphene has been challenging since the graphene surface is hydrophobic while PEDOT:PSS is in an aqueous solution. This problem has been solved by forming a layer of PEDOT:PSS by using oxidative chemical vapor deposition on the graphene surface.

This discussion of known concepts, such as the concepts of several of the above-mentioned prior art documents, clearly shows that some technical challenges remain. Specifically, there is further room for improvement in terms of increased accuracy of position detectors for distance measurements, for two-dimensional sensing or even for three-dimensional sensing. Further, complexity of the optical systems still remains an issue which may be addressed.

### Problem Addressed by the Invention

Therefore, a problem addressed by the present invention is that of specifying a device and a method for optically detecting at least one object which at least substantially avoid the disadvantages of known devices and methods of this type. In particular, an improved simple, cost-efficient, at least partially transparent and, still, reliable transversal detector for determining the lateral position of an object for light beams both in the visible spectral range and in the infrared spectral range, in particular for wavelengths of 380 nm to 15 μm, specifically for wavelengths of 380 nm to 3 μm, would rather be desirable.

### SUMMARY OF THE INVENTION

This problem is solved by the invention with the features of the independent patent claims. Advantageous developments of the invention, which can be realized individually or in combination, are presented in the dependent claims and/or in the following specification and detailed embodiments.

As used herein, the expressions “have”, “comprise” and “contain” as well as grammatical variations thereof are used in a non-exclusive way. Thus, the expression “A has B” as well as the expression “A comprises B” or “A contains B” may both refer to the fact that, besides B, A contains one or more further components and/or constituents, and to the case in which, besides B, no other components, constituents or elements are present in A.

In a first aspect of the present invention, a detector for optical detection, in particular, for determining a position of at least one object, specifically a lateral position of the at least one object, is disclosed.

The “object” generally may be an arbitrary object, chosen from a living object and a non-living object. Thus, as an example, the at least one object may comprise one or more articles and/or one or more parts of an article. Additionally or alternatively, the object may be or may comprise one or more living beings and/or one or more parts thereof, such as one or more body parts of a human being, e.g. a user, and/or an animal.

As used herein, a “position” generally refers to an arbitrary item of information on a location and/or orientation of the object in space. For this purpose, as an example, one or more coordinate systems may be used, and the position of the object may be determined by using one, two, three or more coordinates. As an example, one or more Cartesian coordinate systems and/or other types of coordinate systems may be used. In one example, the coordinate system may be a coordinate system of the detector in which the detector has a predetermined position and/or orientation. As will be outlined in further detail below, the detector may have an optical axis, which may constitute a main direction of view of the detector. The optical axis may form an axis of the coordinate system, such as a z-axis. Further, one or more lateral axes may be provided, preferably perpendicular to the z-axis.

Thus, as an example, the detector may constitute a coordinate system in which the optical axis forms the z-axis and in which, additionally, an x-axis and a y-axis may be provided which are perpendicular to the z-axis and which are perpendicular to each other. As an example, the detector and/or a part of the detector may rest at a specific point in this coordinate system, such as at the origin of this coordinate system. In this coordinate system, a direction parallel or antiparallel to the z-axis may be regarded as a longitudinal direction, and a coordinate along the z-axis may be considered as a longitudinal coordinate. An arbitrary direction perpendicular to the longitudinal direction may be considered as a lateral or a transversal direction, and an x- and/or y-coordinate may be considered as a lateral or a transversal coordinate.

Alternatively, other types of coordinate systems may be used. Thus, as an example, a polar coordinate system may be used in which the optical axis forms a z-axis and in which a distance from the z-axis and a polar angle may be used as additional coordinates. Again, a direction parallel or antiparallel to the z-axis may be considered a longitudinal direction, and a coordinate along the z-axis may be considered a longitudinal coordinate. Any direction perpendicular to the z-axis may be considered a lateral or a transversal direction, and the polar coordinate and/or the polar angle may be considered a lateral or a transversal coordinate.

As used herein, the detector for optical detection generally is a device which is adapted for providing at least one item of information on the position of the at least one object, in particular on the lateral or transversal position of the at least one object. The detector may be a stationary device or a mobile device. Further, the detector may be a stand-alone device or may form part of another device, such as a computer, a vehicle or any other device. Further, the detector may be a hand-held device. Other embodiments of the detector are feasible.

The detector may be adapted to provide the at least one item of information on the position of the at least one object, in particular of the lateral or transversal position of the at least one object, in any feasible way. Thus, the information may e.g. be provided electronically, visually, acoustically or in any arbitrary combination thereof. The information may further be stored in a data storage of the detector or a separate device and/or may be provided via at least one interface, such as a wireless interface and/or a wire-bound interface.

The detector for an optical detection of at least one object according to the present invention comprises:
at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photosensitive layer embedded between at least two conductive layers, wherein at least one of the conductive layers comprises an at least partially transparent graphene layer deposited on an at least partially transparent substrate allowing the light beam to travel to the photosensitive layer, wherein the transversal optical sensor is further adapted to generate at least one transversal sensor signal indicative of the transversal position of the light beam in the photosensitive layer; and
at least one evaluation device, wherein the evaluation device is designed to generate at least one item of information on a transversal position of the object by evaluating the at least one transversal sensor signal.

Herein, the components listed above may be separate components. Alternatively, two or more of the components as listed above may be integrated into one component. Further, the at least one evaluation device may be formed as a separate evaluation device independent from the transfer device and the transversal optical sensors, but may preferably be connected to the transversal optical sensor in order to receive the transversal sensor signal. Alternatively, the at least one evaluation device may fully or partially be integrated into the at least one transversal optical sensor.

As used herein, the term “transversal optical sensor” generally refers to a device which is adapted to determine a transversal or lateral position of at least one light beam traveling from the object to the detector. With regard to the term position, reference may be made to the definition above. Thus, preferably, the transversal position may be or may comprise at least one coordinate in at least one dimension perpendicular to an optical axis of the detector. As an example, the transversal position may be a position of a light spot generated by the light beam in a plane perpendicular to the optical axis, such as on a sensor surface of the transversal optical sensor. As an example, the position in the plane may be given in Cartesian coordinates and/or polar coordinates. Other embodiments are feasible.

Herein, the transversal optical sensor may, preferably, be configured in order to function as a “position sensitive detector” or a “position sensing detector”, both commonly abbreviated to the term, “PSD”, by being capable of providing both of the two lateral components of the spatial position of the object, in particular, simultaneously. As a result, by combining the at least one transversal coordinate of the object with the at least one longitudinal coordinate of the object a three-dimensional position of the object as defined above may, thus, be determined by using the evaluation device. It is also possible that the transversal sensor may be able to, concurrently, detect the longitudinal coordinate.

The transversal optical sensor may provide at least one transversal sensor signal. Herein, the transversal sensor signal may generally be an arbitrary signal indicative of the transversal or a lateral position. As an example, the transversal sensor signal may be or may comprise a digital and/or an analog signal. As an example, the transversal sensor signal may be or may comprise a voltage signal and/or a current signal. Additionally or alternatively, the transversal sensor signal may be or may comprise digital data related to the voltage signal or the current signal, respectively. The transversal sensor signal may comprise a single signal value and/or a series of signal values. The transversal sensor signal may further comprise an arbitrary signal which may be derived by combining two or more individual signals, such as by averaging two or more signals and/or by forming a quotient of two or more signals.

According to the present invention, at least one photosensitive layer is sandwiched by at least two conductive layers, which may also be denominated as first conductive layer and as second conductive layer. However, other kinds of denominations may also be possible. As generally used, the term “layer” refers to refers to an element having an elongated shape and a thickness, wherein an extension of the element in a lateral dimension exceeds the thickness of the element, such as by at least a factor of 10, preferably of 20, more preferably of 50 and most preferably of 100 or more. This definition may also be applicable to other kinds of layers, such as a cover layer, a blocking layer, or a transporting layer. As mentioned above, each of the at least two conductive layers may, thus, be arranged in a fashion that a direct electrical contact between the respective conductive layer and the embedded photosensitive layer may be achieved, particularly in order to acquire the transversal sensor signal with as little loss as possible, such as due to additional resistances between the adjacent layers as well. Thus, the two individual conductive layers may, preferably, be arranged in form of a sandwich structure, i.e. in a manner that a thin photosensitive film may adjoin both of the two conductive layers while the two conductive layers may be separated from each other.

Surprisingly, it has been found that a setup in which at least one of the conductive layers, i.e. the first conductive layer in the following, comprises an at least partially transparent graphene layer which deposited on an at least partially transparent substrate is particularly advantageous for this purpose, thus, allowing the light beam to travel to the photosensitive layer. As a result, graphene may, thus, be employed as a transparent conducting material (TCM), in particular for both the visual spectral range and the infrared (IR) spectral range, more particular for a spectral range of 380 nm to 15 μm, especially for the spectral range of 380 nm to 3 μm, specifically for the spectral of 1 μm to 3 μm, as described below in more detail. It is emphasized that this feature is particular contrast to the disclosure of WO 2014/097181 A1 and WO 2016/120392 A1, wherein the graphene can be employed as alternative to a metal electrode as one of the split electrodes which are used for reading out the information required for determining the transversal position of the light beam within the sensor area.

In accordance with the present invention, the transversal optical sensor is indicative of the transversal position of the light beam in the photosensitive layer when the transversal sensor signal is dependent on a position of the light beam within the photosensitive layer. This effect can, in general, be achieved by Ohmic losses, which may also be denominated as “resistive losses”, occurring on a way from a location of generation and/or modification of electrical charge carriers within the photosensitive layer via the graphene layer to one or more conductive layers, such as to the split electrode. Thus, in order to provide the desired Ohmic losses on the way from the location of the generation and/or modification of the electric charge carriers to the electrodes, the first conductive layer may, preferably, exhibit a higher electrical resistance compared to the electrical resistance of the electrodes and, concurrently, a lower electrical resistance compared to the electrical resistance of the photosensitive layer, thus, being adapted for guiding a current always along a path with the lowest Ohmic losses, respectively.

Herein, the at least partially transparent graphene layer appears to be particularly suited for achieving favorable electrical conduction within a plane due to advantageous anisotropic charge carrier transport properties which occur in graphene. Hence the functional but thin graphene layer may be obtained, wherein, as described below in more detail, the graphene layer may at least be partially transparent in at least a partition of the electromagnetic spectrum, preferably in the partition of the electromagnetic spectrum in which a material within the photosensitive layer may be able to provide charge carriers by interacting with electromagnetic radiation provided by the light beam and transmitted through the transparent conductive layer. More particular, as illustrated below, it could be experimentally verified that the graphene layer may exhibit a transmission above 80% in a wavelength range of 0.38 μm to 3 μm. As a result, the present detector may, especially, be applicable in a case in which the light beam may exhibit at least one wavelength in the visual spectral range of 380 nm to 760 nm or in the infrared spectral range above 760 nm to 1000 μm, in particular in the wavelength range of 380 nm to 15 μm, especially in the wavelength range of 380 nm to 3 μm, specifically in the wavelength range of 1 μm to 3 μm. Particularly, in order to achieve a high transmission through the first conductive layer, the substrate which may be adapted for carrying the graphene layer may, advantageously, at least be partially transparent in the infrared spectral range, in particular in the same wavelength range of 380 nm to 3 μm, specifically in the wavelength range of 1 μm to 3 μm. For the purposes of the present invention, the substrate adapted for carrying the graphene layer may, thus, preferably comprise a material that may be selected from the group consisting of quartz glass, sapphire, fused silica, silicon, germanium, zinc selenide, zinc sulfide, silicon carbide, aluminum oxide, calcium fluoride, magnesium fluoride, sodium chloride, or potassium bromide. It may be noted that this advantageous property is in particular contrast to other generally used partially transparent materials, such as indium tin oxide (ITO) or fluorine-doped tin oxide (SnO2:F; FTO), a layer of which proves to be unsuitable in the optical detector since it does not provide sufficient transparency within the infrared (IR) spectral range as desired for the purposes of the present invention.

Further, the use of graphene as the first conductive layer may exhibit additional advantages, especially with regard to production of the graphene layer. Particularly, graphene turns out to be insoluble in most solvents which may, generally, be used in a deposition of photosensitive materials, such as nanoparticles or organic semiconductors. The resulting graphene layers appear to be thermally stable. In particular, by controlling thickness and growth properties of the graphene, graphene layers which may exhibit a wide range of sheet resistances can be produced. Preferably, the graphene layer can be tuned to exhibit an electrical sheet resistance that may be advantageous for application as transversal optical sensor. In addition, the sheet resistance can further be reduced, especially by breaking C—C bonds of the graphene in an oxidizing environment, such as by applying O₂ plasma to the graphene layer. Consequently, it may be accomplished in a particularly preferred embodiment that the graphene layer may exhibit a high electrical sheet resistance, in particular of 100 Ω/sq to 20000 Ω/sq, preferably of 100 Ω/sq to 10 000 Ω/sq, more preferred 125 of Ω/sq to 1000 Ω/sq, specifically of 150 of Ω/sq to 500 Ω/sq. As generally used, the unit “Ω/sq” or “Ω/square” is dimensionally equal to the SI unit Ω but exclusively reserved for the sheet resistance. By way of example, a square sheet having the sheet resistance of 10 Ω/sq has an actual resistance of 10Ω, regardless of the size of the square. As a result of the sheet resistance being in the indicated range, the photosensitive layer embedded between the at least two conductive layers and, preferably, equipped with the at least one separate split electrode may act as the transversal detector.

In particular, the graphene can be placed on the substrate via a deposition method, wherein the deposition method may, preferably, be selected from a chemical vapor deposition (CVD), a mechanical exfoliation, a chemically derived graphene, and a growth from silicon carbide. In particular, the graphene may be obtained by a chemical vapor deposition (CVD), more preferred a low pressure chemical vapor deposition (LP-CVD), especially by the method as discloses in N.-E. Weber et al., cited above. Accordingly, the growth of graphene can be carried out, without the aid of any metallic species or catalysts, in a tube furnace, at temperatures of 1000° C. to 1050° C., chamber pressures of 3 to 5 mbar and a gas mixture of CO2: CH₄ 3: 30 sccm.

Further, since the incident light beam may already reach the photosensitive layer on a path through the graphene layer acting as the first conductive layer, the second conductive layer may exhibit at least partially intransparent properties with respect to the incident light beam. Thus, the second conductive layer may be selected from a metal sheet or a low-resistive graphene sheet, wherein the metal sheet may comprise one or more of silver, copper, aluminum, platinum, magnesium, chromium, titanium, or gold, and wherein the low-resistive graphene sheet may have an electrical sheet resistance below 100 Ω/sq, preferably of 1 Ω/sq or below.

In an alternative embodiment, the second conductive layer can, however, also exhibit at least partially transparent properties with respect to the incident light beam. This may, in particular, allow guiding the incident light beam to the photosensitive layer through the first conductive layer and/or through the second conductive layer, such as in a concurrent manner, in an alternating fashion, or a combination thereof. For this purpose, the second conductive layer may comprise an at least partially transparent semiconducting material, wherein the semiconducting material may, preferably, be selected from the group comprising an at least partially transparent semiconducting metal oxide or a doped variant thereof. However, selecting the semiconducting material, especially, from at least one transparent metal oxide, in particular from indium tin oxide (ITO), fluorine-doped tin oxide (SnO2:F; FTO), magnesium oxide (MgO), aluminum zinc oxide (AZO), antimony tin oxide (SnO₂/Sb₂O₅), or a perovskite transparent conductive oxide, such as SrVO₃, or CaVO₃, or, alternatively, from metal nanowires, such as Ag nanowires, may not be sufficient since, as indicated above, they may not provide a sufficient transparency within a desired partition of the spectral range, in particular, not within the infrared spectral range of above 760 nm to 15 μm, specifically of 1 μm to 3 μm.

Therefore, the second conductive layer selected to exhibit at least partially optically transparent properties may, thus, comprise a further graphene layer that may be used in a similar manner as the first conductive layer as described above in more detail. Alternatively or in addition, a layer of a transparent electrically conducting organic polymer may also be employed for this purpose. Herein, poly(3,4-ethylenedioxythiophene) (PEDOT) or a dispersion of PEDOT and a polystyrene sulfonic acid (PEDOT:PSS) may be selected as the transparent electrically conducting polymer. On the other hand, in case one of the conductive layers may already be at least partially transparent, a larger variety of different materials, including optically intransparent materials, may be employed for the second conductive layer.

In particular, for the purpose of recording the transversal optical signal, the transversal optical sensor may comprise a separate split electrode having at least two partial electrodes, wherein the split electrode may be or comprise a separate entity apart from the graphene layer. Thus, the transversal sensor signal can indicate a position of a light spot generated by the light beam within the photosensitive layer of the transversal optical sensor as long as the conductive layer at which the split electrode is located may exhibit a higher electrical resistance compared to the electrical resistance of the corresponding split electrode. Generally, as used herein, the term “partial electrode” refers to an electrode out of a plurality of electrodes, adapted for measuring at least one current and/or voltage signal, preferably independent from other partial electrodes. Thus, in case a plurality of partial electrodes is provided, the respective electrode is adapted to provide a plurality of electric potentials and/or electric currents and/or voltages via the at least two partial electrodes, which may be measured and/or used independently. Further, in particular for allowing a better electronic contact, the split electrode having the at least two partial electrodes which may each comprise a metal contact may be arranged on top of one of the conductive layers, preferably, on top of the second conductive layer which may comprise the layer of the electrically conducting polymer. Herein, the split electrode may, preferably, comprise evaporated metal contacts, additionally, arranged on top of the second conductive layer which may comprise the layer of the electrically conducting polymer, wherein the evaporated metal contacts may, in particular, comprise one or more of silver, aluminum, platinum, titanium, chromium, or gold; or, alternatively a layer of low-resistive graphene as described above. However, other kinds of arrangements of the split electrode within the transversal optical sensor may also be feasible. Herein, the metal contact may, preferably, be one of an evaporated contact or a sputtered contact or, alternatively, a printed contact or a coated contact, for which manufacturing a conductive ink may be employed.

The transversal optical sensor may further be adapted to generate the transversal sensor signal in accordance with the electrical currents through the partial electrodes. Thus, a ratio of electric currents through two horizontal partial electrodes may be formed, thereby generating an x-coordinate, and/or a ratio of electric currents through to vertical partial electrodes may be formed, thereby generating a y-coordinate. The detector, preferably the transversal optical sensor and/or the evaluation device, may be adapted to derive the information on the transversal position of the object from at least one ratio of the currents through the partial electrodes. Other ways of generating position coordinates by comparing currents through the partial electrodes are feasible.

The partial electrodes may generally be defined in various ways, in order to determine a position of the light beam in the photosensitive layer. Thus, two or more horizontal partial electrodes may be provided in order to determine a horizontal coordinate or x-coordinate, and two or more vertical partial electrodes may be provided in order to determine a vertical coordinate or y-coordinate. In particular, in order to maintain as much area as possible for measuring the transversal position of the light beam, the partial electrodes may be provided at a rim of the transversal optical sensor, wherein an interior space of the transversal optical sensor is covered by the second conductive layer. Preferably, the split electrode may comprise four partial electrodes which are arranged at four sides of a square or a rectangular transversal optical sensor. Alternatively, the transversal optical sensor may be of a duo-lateral type, wherein the duo-lateral transversal optical sensor may comprise two separate split electrodes each being located at one of the two conductive layers which embed the photosensitive layer, wherein each of the two conductive layers may exhibit a higher electrical resistance compared to the corresponding split electrode. However, other embodiments may also be feasible, in particular, depending on the form of the transversal optical sensor. As described above, the second conductive layer material may, preferably, be a transparent electrode material, such as a transparent conductive oxide and/or, most preferably, a transparent conductive polymer, which may exhibit a higher electrical resistance compared to the split electrode.

By using the transversal optical sensor, wherein one of the electrodes is the split electrode with the two or more partial electrodes, currents through the partial electrodes may be dependent on a position of the light beam within the photosensitive layer, which may, thus, also be denominated as a “sensor area” or “sensor region”. This kind of effect may generally be due to the fact that Ohmic losses or resistive losses may occur for an electrical charge carrier on the way from a location of the impinging light onto the photosensitive layer to the partial electrodes. Thus, due to the Ohmic losses on the way from the location of generation and/or modification of the charge carriers to the partial electrodes through the first conductive layer, the respective currents through the partial electrodes depend on the location of the generation and/or modification of the charge carriers and, thus, to the position of the light beam in the photosensitive layer. In order to accomplish a closed circuit for the electrons and/or holes, the second conductive layer as described above may, preferably, be employed. For further details with regard to determining the position of the light beam, reference may be made to the preferred embodiments below, to the disclosure of WO 2014/097181 A1, WO 2016/120392 A1, the further references cited therein.

As already mentioned above, the transversal optical sensor has at least one photosensitive layer which is embedded between at least two conductive layers, wherein a single photosensitive layer embedded between two individual conductive layers may particularly be preferred. Herein, the photosensitive layer is or comprises a photosensitive material, which may also be denoted as a photoactive material and which, as generally used, refers to a material in which, upon impingement of an incident light beam, an electrical property of the material may be changed. As already mentioned above, the incident light beam may, thus, cause a generation of charge carriers and/or a modification of charge carriers in the photosensitive material at least at a location where the light beam impinges on the photosensitive material. As generally used, the photosensitive material may be denoted as “photovoltaic material” when which charge carriers are generated by the incident light beam. Alternatively, the photosensitive material may be denominated as “photoconductive material” when the flow of charge carriers is modified by the incident light beam, whereby the electrical conductivity of the photosensitive material may be affected. More particular, the photosensitive material may, thus, be selected from an inorganic or organic photovoltaic material, from an inorganic or organic photoconductive material, or from a plurality of colloidal quantum dots (CQD) which may comprise an inorganic photovoltaic or photoconductive material.

In general, the photosensitive material may comprise one or more materials as, in particular, disclosed in WO 2014/097181 A1, WO 2016/120392 A1, or European patent application Ser. No. 16165905.7, filed Apr. 19, 2016, the content of which is incorporated here by reference.

More particular, the photoconductive material as used for the photosensitive material may, preferably, comprise an inorganic photoconductive material, an organic photoconductive material, a combination, a solid solution, and/or a doped variant thereof. In this regard, the inorganic photoconductive material may, in particular, comprise one or more of selenium, tellurium, a selenium-tellurium alloy, a metal oxide, a group IV element or compound, i.e. an element from group IV or a chemical compound with at least one group IV element, a group III-V compound, i.e. a chemical compound with at least one group III element and at least one group V element, a group II-VI compound, i.e. a chemical compound with, on one hand, at least one group II element or at least one group XII element and, on the other hand, at least one group VI element, and/or a chalcogenide. However, other inorganic photoconductive materials may equally be appropriate.

As mentioned above, the chalcogenide, preferably selected from a group comprising sulfide chalcogenides, selenide chalcogenides, telluride chalcogenides, ternary chalcogenides, quaternary and higher chalcogenides, may preferably be appropriate to be used as the photoconductive material. As generally used, the term “chalcogenide” refers to a compound which may comprise a group 16 element of the periodic table apart from an oxide, i.e. a sulfide, a selenide, and a telluride. In particular, the photoconductive material may be or comprise a sulfide chalcogenide, preferably lead sulfide (PbS), a selenide chalcogenide, preferably lead selenide (PbSe), a telluride chalcogenide, preferably, cadmium telluride (CdTe), or a ternary chalcogenide is, preferably mercury zinc telluride (HgZnTe; MZT). Since at least the mentioned preferred photoconductive materials are, generally, known to exhibit a distinctive absorption characteristic within the visual spectral range and/or infrared spectral range, the optical sensor having the layer which comprises the mentioned preferred photoconductive material may, preferably, be used as a visual light sensor and/or an infrared sensor. However, other embodiments and/or other photoconductive materials, in particular, the photoconductive materials as described below, may also be feasible.

In particular, the sulfide chalcogenide may be selected from a group comprising lead sulfide (PbS), cadmium sulfide (CdS), zinc sulfide (ZnS), mercury sulfide (HgS), silver sulfide (Ag₂S), manganese sulfide (MnS), bismuth trisulfide (Bi₂S₃), antimony trisulfide (Sb₂S₃), arsenic trisulfide (As₂S₃), tin (II) sulfide (SnS), tin (IV) disulfide (SnS₂), indium sulfide (In₂S₃), copper sulfide (CuS or Cu₂S), cobalt sulfide (CoS), nickel sulfide (NiS), molybdenum disulfide (MoS₂), iron disulfide (FeS₂), and chromium trisulfide (CrS₃).

In particular, the selenide chalcogenide may be selected from a group comprising lead selenide (PbSe), cadmium selenide (CdSe), zinc selenide (ZnSe), bismuth triselenide (Bi₂Se₃), mercury selenide (HgSe), antimony triselenide (Sb₂Se₃), arsenic triselenide (As₂Se₃), nickel selenide (NiSe), thallium selenide (TISe), copper selenide (CuSe or Cu₂Se), molybdenum diselenide (MoSe₂), tin selenide (SnSe), and cobalt selenide (CoSe), and indium selenide (In₂Se₃). Further, solid solutions and/or doped variants of the mentioned compounds or of other compounds of this kind may also be feasible.

In particular, the telluride chalcogenide may be selected from a group comprising lead telluride (PbTe), cadmium telluride (CdTe), zinc telluride (ZnTe), mercury telluride (HgTe), bismuth tritelluride (Bi₂Te₃), arsenic tritelluride (As₂Te₃), antimony tritelluride (Sb₂Te₃), nickel telluride (NiTe), thallium telluride (TlTe), copper telluride (CuTe), molybdenum ditelluride (MoTe₂), tin telluride (SnTe), and cobalt telluride (CoTe), silver telluride (Ag₂Te), and indium telluride (In₂Te₃). Further, solid solutions and/or doped variants of the mentioned compounds or of other compounds of this kind may also be feasible.

In particular, the ternary chalcogenide may be selected from a group comprising mercury cadmium telluride (HgCdTe; MCT), mercury zinc telluride (HgZnTe), mercury cadmium sulfide (HgCdS), lead cadmium sulfide (PbCdS), lead mercury sulfide (PbHgS), copper indium disulfide (CuInS₂; CIS), cadmium sulfoselenide (CdSSe), zinc sulfoselenide (ZnSSe), thallous sulfoselenide (TISSe), cadmium zinc sulfide (CdZnS), cadmium chromium sulfide (CdCr₂S₄), mercury chromium sulfide (HgCr₂S₄), copper chromium sulfide (CuCr₂S₄), cadmium lead selenide (CdPbSe), copper indium diselenide (CuInSe₂), indium gallium arsenide (InGaAs), lead oxide sulfide (Pb₂OS), lead oxide selenide (Pb₂OSe), lead sulfoselenide (PbSSe), arsenic selenide telluride (As₂Se₂Te), cadmium selenite (CdSeO₃), cadmium zinc telluride (CdZnTe), and cadmium zinc selenide (CdZnSe), further combinations by applying compounds from the above listed binary chalcogenides and/or binary III-V-compounds as listed below. Further, solid solutions and/or doped variants of the mentioned compounds or of other compounds of this kind may also be feasible.

With regard to quaternary and higher chalcogenides, this kind of material may be selected from a quaternary and higher chalcogenide which may be known to exhibit suitable photoconductive properties. In particular, a compound having a composition of Cu(In, Ga)S/Se₂ or of Cu₂ZnSn(S/Se)₄ may be feasible for this purpose.

With regard to the III-V compound, this kind of semiconducting material may be selected from a group comprising indium antimonide (InSb), boron nitride (BN), boron phosphide (BP), boron arsenide (BAs), aluminum nitride (AlN), aluminum phosphide (AlP), aluminum arsenide (AlAs), aluminum antimonide (AlSb), indium nitride (InN), indium phosphide (InP), indium arsenide (InAs), indium antimonide (InSb), gallium nitride (GaN), gallium phosphide (GaP), gallium arsenide (GaAs), and gallium antimonide (GaSb). Further, solid solutions and/or doped variants of the mentioned compounds or of other compounds of this kind may also be feasible.

With regard to the II-VI compound, this kind of semiconducting material may be selected from a group comprising cadmium sulfide (CdS), cadmium selenide (CdSe), cadmium telluride (CdTe), zinc sulfide (ZnS), zinc selenide (ZnSe), zinc telluride (ZnTe), mercury sulfide (HgS), mercury selenide (HgSe), mercury telluride (HgTe), cadmium zinc telluride (CdZnTe), mercury cadmium telluride (HgCdTe), mercury zinc telluride (HgZnTe), and mercury zinc selenide (CdZnSe). However, other II-VI compounds may be feasible. Further, solid solutions of the mentioned compounds or of other compounds of this kind may also be applicable.

With regard to the metal oxides, this kind of semiconducting material may be selected from a known metal oxide which may exhibit photoconductive properties, particularly from the group comprising copper (II) oxide (CuO), copper (I) oxide (CuO₂), nickel oxide (NiO), zinc oxide (ZnO), silver oxide (Ag₂O), manganese oxide (MnO), titanium dioxide (TiO₂), barium oxide (BaO), lead oxide (PbO), cerium oxide (CeO₂), bismuth oxide (Bi₂O₃), cadmium oxide (CdO), ferrite (Fe₃O₄), and perovskite oxides (ABO₃, wherein A is a divalent cation, and B a tetravalent cation). In addition, ternary, quarternary or higher metal oxides may also be applicable. Furthermore, solid solutions and/or doped variants of the mentioned compounds or of other compounds of this kind, which could be stoichiometric compounds or off-stoichiometric compounds, may also be feasible. As explained later in more detail, it may be preferable to select a metal oxide which might, simultaneously, also exhibit transparent or translucent properties.

With regard to a group IV element or compound, this kind of semiconducting material may be selected from a group comprising doped diamond (C), doped silicon (Si), silicon carbide (SiC), silicon germanium (SiGe), and doped germanium (Ge), wherein the semiconducting material may be selected from a crystalline material, a microcrystalline material, or, preferably, from an amorphous material. As generally used, the term “amorphous” refers to a non-crystalline allotropic phase of the semiconducting material. In particular, the photoconductive material may comprise at least one hydrogenated amorphous semiconducting material, wherein the amorphous material has, in addition, been passivated by applying hydrogen to the material, whereby, without wishing to be bound by theory, a number of dangling bonds within the material appear to have been reduced by several orders of magnitude. In particular, the hydrogenated amorphous semiconducting material may be selected from a group consisting of hydrogenated amorphous silicon (a-Si:H), a hydrogenated amorphous silicon carbon alloy (a-SiC:H), or a hydrogenated amorphous germanium silicon alloy (a-GeSi:H). However, other kinds of materials, such as hydrogenated microcrystalline silicon (pc-Si:H), may also be used for these purposes.

Alternatively or in addition, the organic photoconductive material may, in particular, be or comprise an organic compound, in particular an organic compound which may be known to comprise appropriate photoconductive properties, preferably polyvinylcarbazole, a compound which is generally used in xerography. However, a large number of other organic molecules which are described in WO 2016/120392 A1 in more detail may also be feasible.

In a further preferred embodiment, the photoconductive material may be provided in form of a colloidal film which may comprise quantum dots. This particular state of the photoconductive material which may exhibit slightly or significantly modified chemical and/or physical properties with respect to a homogeneous layer of the same material may, thus, also be denoted as colloidal quantum dots (CQD). As used herein, the term “quantum dots” refers to a state of the photoconductive material in which the photoconductive material may comprise electrically conducting particles, such as electrons or holes, which are confined in all three spatial dimensions to a small volume that is usually denominated as a “dot”. Herein, the quantum dots may exhibit a size which can, for simplicity, be considered as diameter of a sphere that might approximate the mentioned volume of the particles. In this preferred embodiment, the quantum dots of the photoconductive material may, in particular, exhibit a size from 1 nm to 100 nm, preferably from 2 nm to 100 nm, more preferred from 2 nm to 15 nm, provided that the quantum dots actually comprised in a specific thin film may exhibit a size being below the thickness of the specific thin film. In practice, the quantum dots may comprise nanometer-scale semiconductor crystals which might be capped with surfactant molecules and dispersed in a solution in order to form the colloidal film. Herein, the surfactant molecules may be selected to allow determining an average distance between the individual quantum dots within the colloidal film, in particular, as a result from approximate spatial extensions of the selected surfactant molecules. Further, depending on the synthesis of ligands, quantum dots may exhibit hydrophilic or hydrophobic properties. The CQD can be produced by applying a gas-phase, a liquid-phase, or a solid-phase approach. Hereby, various ways for a synthesis of the CQD are possible, in particular by employing known processes such as thermal spraying, colloidal synthesis, or plasma synthesis. However, other production processes may also be feasible.

Further in this preferred embodiment, the photoconductive material used for the quantum dots may, preferably, be selected from one of the photoconductive materials as mentioned above, more particular, from the group comprising lead sulfide (PbS), lead selenide (PbSe), lead telluride (PbTe), cadmium telluride (CdTe), indium phosphide (InP), cadmium sulfide (CdS), cadmium selenide (CdSe), indium antimonide (InSb), mercury cadmium telluride (HgCdTe; MCT), copper indium sulfide (CIS), copper indium gallium selenide (CIGS), zinc sulfide (ZnS), zinc selenide (ZnSe), a perovskite structure materials ABC₃, wherein A denotes an alkaline metal or an organic cation, B=Pb, Sn, or Cu, and C a halide, and copper zinc tin sulfide (CZTS). Further, solid solutions and/or doped variants of the mentioned compounds or of other compounds of this kind may also be feasible. Core shell structures of the materials of this kind of materials may also be feasible. However, kinds of other materials may also be feasible.

Thus, the photosensitive layer material may, in a particular embodiment, be obtained by providing a thin film comprising colloidal quantum dots (CQD). Herein, the CQD film may, preferably, be deposited onto a conductive layer. For this purpose, the CQD film may be provided as a solution of the quantum dots in a nonpolar organic solvent, wherein the solvent may, preferably, be selected from the group comprising octane, toluene, cyclohexane, n-heptane, benzene, chlorobenzene, acetonitrile, dimethylformamide (DMF), and chloroform. Preferably, the quantum dots may be provided in a concentration from 10 mg/ml to 200 mg/ml, preferably from 50 mg/ml to 100 mg/ml, in the organic solvent. Generally, the CQD film may, preferably, be provided by a deposition method, preferably by a coating method, more preferred by a spin-coating or slot coating; by ink-jet printing; or by a blade coating method. Preferably, the CQD film may undergo a treatment with an organic agent, wherein the organic agent may, preferably, be selected from the group comprising thioles and amines, in particular from butylamine, 1,2-ethanedithiol (edt), 1,2- and 1,3-benzenedithiol (bdt), and or oleic acid. By way of example, for treatment of a colloidal film which comprises lead sulfide quantum dots (PbS CQD), the organic agent butylamine has successfully been employed. After the treatment with the organic agent, the CQD film may, preferably, be dried at a temperature from 50° C. to 250° C., preferably from 80° C. to 220° C., more preferred from 100° C. to 200° C. at air.

In a further preferred embodiment, the transversal optical sensor may be arranged as at least one photodiode. Herein, the photodiode may have at least one photosensitive layer comprising at least one electron donor material and at least one electron acceptor material, wherein this kind of photosensitive layer is embedded between the conductive layers as described above. As generally used, the term “photodiode” relates to a device being capable of converting a fraction of incident light into an electrical current. With particular regard to the present invention, the photodiode as used here may be employed as the transversal optical sensor for the detector according to the present invention.

In a particularly preferred embodiment, the photosensitive layer has, on one hand, at least one electron donor material comprising a donor polymer, in particular an organic donor polymer, and, on the other hand, at least one electron acceptor material, in particular, a small acceptor molecule, preferably selected from the group comprising a fullerene-based electron acceptor material, tetracyanoquinodimethane (TCNQ), a perylene derivate, an acceptor polymer, and inorganic nanocrystals. Herein, the electron donor material may, thus, comprise a donor polymer while the electron acceptor material may comprise an acceptor polymer. In a particular embodiment, a copolymer may, simultaneously, be constituted in a manner that it may comprise a donor polymer unit and an acceptor polymer unit and may, therefore, also be denominated as a “push-pull copolymer” based on the respective functions of each of the units of the copolymer. However, the electron donor material and the electron acceptor material may, preferably, be comprised within the photosensitive layer in form of a mixture. As generally used, the term “mixture” relates to a blend of two or more individual compounds, wherein the individual compounds within the mixture maintain their chemical identity. In a particularly preferred embodiment, the mixture employed in the photosensitive layer according to the present invention may comprise the electron donor material and the electron acceptor material in a ratio from 1:100 to 100:1, more preferred from 1:10 to 10:1, in particular in a ratio of from 1:2 to 2:1, such as 1:1. However, other ratios of the respective compounds may also be applicable, in particular depending on the kind and number of individual compounds being involved. Preferably, the electron donor material and the electron acceptor material may constitute an interpenetrating network of donor and acceptor domains within the photosensitive layer, wherein interfacial areas between the donor and acceptor domains may be present, and wherein percolation pathways may connect the domains to the electrodes. In particular, the donor domains may, thus, connect the electrode which assumes a function of a hole extracting contact while the acceptor domains may, thus, contact the electrode which assumes the function of an electron extracting contact. As used herein, the term “donor domain” refers to a region within the photosensitive layer in which the electron donor material may predominantly, particularly completely, be present. Similarly, the term “acceptor domain” refers to a region within the photosensitive layer in which the electron acceptor material may predominantly, in particular completely, be present. Herein, the domains may exhibit areas, which are denominated as the “interfacial areas”, which allow a direct contact between the different kinds of regions. Further, the term “percolation pathways” refers to conductive paths within the photosensitive layer along which a transport of electrons or holes, respectively, may predominantly take place.

As mentioned above, the at least one electron donor material may, preferably, comprise a donor polymer, in particular an organic donor polymer. As used herein, the term “polymer” refers to a macromolecular composition generally comprising a large number of molecular repeat units which are usually denominated as “monomers” or “monomeric units”. For the purposes of the present invention, however, a synthetic organic polymer may be preferred. Within this regard, the term “organic polymer” refers to the nature of the monomeric units which may, generally, be attributed as organic chemical compounds. As used herein, the term “donor polymer” refers to a polymer which may particularly be adapted to provide electrons as the electron donor material.

Preferably, the donor polymer may comprise a conjugated system, in which delocalized electrons may be distributed over a group of atoms being bonded together by alternating single and multiple bonds, wherein the conjugated system may be one or more of cyclic, acyclic, and linear. Thus, the organic donor polymer may, preferably, be selected from one or more of the following polymers:
poly[3-hexylthiophene-2,5.diyl] (P3HT),
poly[3-(4-n-octyl)-phenylthiophene] (POPT),
poly[3-10-n-octyl-3-phenothiazine-vinylenethiophene-co-2,5-thiophene] (PTZV-PT), poly[4,8-bis[(2-ethylhexyl)oxy]benzo[1,2-b:4,5-b]dithiophene-2,6-diyl][3-fluoro-2-[(2-ethylhexyl)carbonyl]thieno[3,4-b]thiophenediyl] (PTB7),
poly[thiophene-2,5-diyl-alt-[5,6-bis(dodecyloxy)benzo[c][1,2,5]thiadiazole]-4,7-diyl] (PBT-T1),
poly[2,6-(4,4-bis-(2-ethylhexyl)-4H-cyclopenta[2,1-b;3,4-b]dithiophene)-alt-4,7(2,1,3-benzothiadiazole)] (PCPDTBT),
poly[5,7-bis(4-decanyl-2-thienyl)-thieno(3,4-b)diathiazolethiophene-2,5] (PDDTT),
poly[N-9′-heptadecanyl-2,7-carbazole-alt-5,5-(4′,7′-di-2-thienyl-2′,1′, 3′-benzothiadiazole)] (PCDTBT), or
poly[(4,4′-bis(2-ethylhexyl)dithieno[3,2-b;2′,3′-d]silole)-2,6-diyl-alt-(2,1,3-benzothia-diazole)-4,7-diyl] (PSBTBT),
poly[3-phenylhydrazone thiophene] (PPHT),
poly[2-methoxy-5-(2-ethylhexyloxy)-1,4-phenylenevinylene] (MEH-PPV),
poly[2-methoxy-5-(2′-ethylhexyloxy)-1,4-phenylene-1,2-ethenylene-2,5-dimethoxy-1,4-phenylene-1,2-ethenylene] (M3EH-PPV),
poly[2-methoxy-5-(3′,7′-dimethyloctyloxy)-1,4-phenylenevinylene] (MDMO-PPV),
poly[9,9-di-octylfluorene-co-bis-N,N-4-butylphenyl-bis-N,N-phenyl-1,4-phenylenediamine] (PFB),
   or a derivative, a modification, or a mixture thereof.

However, other kinds of donor polymers or further electron donor materials may also be suitable, in particular polymers which are sensitive in the visual spectral range and/or in the infrared spectral range, especially in the near infrared range above 1000 nm, preferably diketopyrrolopyrrol polymers, in particular, the polymers as described in EP 2 818 493 A1, more preferably the polymers denoted as “P-1” to “P-10” therein; benzodithiophene polymers as disclosed in WO 2014/086722 A1, especially diketopyrrolopyrrol polymers comprising benzodithiophene units; dithienobenzofuran polymers according to US 2015/0132887 A1, especially dithienobenzofuran polymers comprising diketo-pyrrolopyrrol units; phenantro[9,10-B]furan polymers as described in US 2015/0111337 A1, especially phenantro[9,10-B]furan polymers which comprise diketopyrrolopyrrol units; and polymer compositions comprising diketopyrrolopyrrol oligomers, in particular, in an oligomer-polymer ratio of 1:10 or 1:100, such as disclosed in US 2014/0217329 A1.

As further mentioned above, the electron acceptor material may, preferably, comprise a fullerene-based electron acceptor material. As generally used, the term “fullerenes” refers to cage-like molecules of pure carbon, including Buckminster fullerene (C60) and the related spherical fullerenes. In principle, the fullerenes in the range of from C20 to C2000 may be used, the range C60 to C96 being preferred, particularly C60, C70 and C84. Mostly preferred are fullerenes which are chemically modified, in particular one or more of:
[6,6]-phenyl-C61-butyric acid methyl ester (PC60BM),
[6,6]-Phenyl-C71-butyric acid methyl ester (PC70BM),
[6,6]-phenyl C84 butyric acid methyl ester (PC84BM), or
   an indene-C60 bisadduct (ICBA),
      but also dimers comprising one or two C60 or C70 moieties, in particular
   a diphenylmethanofullerene (DPM) moiety comprising one attached oligoether (OE) chain (C70-DPM-OE), or
   a diphenylmethanofullerene (DPM) moiety comprising two attached oligoether (OE) chains (C70-DPM-OE2),
      or a derivative, a modification, or a mixture thereof. However, TCNQ, or a perylene derivative may also be suitable.

Alternatively or in addition, the electron acceptor material may, preferably, comprise inorganic nanocrystals, in particular, selected from cadmium selenide (CdSe), cadmium sulfide (CdS), copper indium sulfite (CuInS₂), or lead sulfide (PbS). Herein, the inorganic nanocrystals may be provided in form of spherical or elongate particles which may comprise a size from 2 nm to 20 nm, preferably from 2 nm to 10 nm, and which may from a blend with a selected donor polymer, such as a composite of CdSe nanocrystals and P3HT or of PbS nanoparticles and MEH-PPV. However, other kinds of blends may also be suitable.

Alternatively or in addition, the electron acceptor material may, preferably, comprise an acceptor polymer. As used herein, the term “acceptor polymer” refers to a polymer which may particularly be adapted to accept electrons as the electron acceptor material. Generally, conjugated polymers based on cyanated poly(phenylenevinylene), benzothiadiazole, perylene or naphthalenediimide are preferred for this purpose. In particular, the acceptor polymer may, preferably, be selected from one or more of the following polymers:
a cyano-poly[phenylenevinylene] (CN-PPV), such as C6-CN-PPV or C8-CN-PPV,
poly[5-(2-(ethylhexyloxy)-2-methoxycyanoterephthalyliden] (MEH—CN-PPV),
poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV),
poly[1,4-dioctyloxyl-p-2,5-dicyanophenylenevinylene] (DOCN-PPV),
poly[9,9′-dioctylfluoreneco-benzothiadiazole] (PF8BT),
   or a derivative, a modification, or a mixture thereof. However, other kinds of acceptor polymers may also be suitable.

For more details concerning the mentioned compounds which may be used as the donor polymer or the electron acceptor material, reference may be made to the above-mentioned review articles by L. Biana et al., A. Facchetti, and S. Günes et al., as well as the respective references cited therein. Further compounds are described in the dissertation of F. A. Sperlich, Electron Paramagnetic Resonance Spectroscopy of Conjugated Polymers and Fullerenes for Organic Photovoltaics, Julius-Maximilians-Universität Würzburg, 2013, and the references cited therein.

In a particular embodiment, at least one kind of charge-influencing layer may be placed in the photodiode with respect to the photosensitive layer in an adjacent fashion, wherein the charge-influencing layer may comprise a charge-carrier blocking layer or a charge-carrier transporting layer. As generally used, the term “charge carrier” relates to electrons or holes adapted to provide, block and/or transport electrical charge carriers within a material. Consequently, the term “charge-influencing layer” or, alternatively, the term “charge-manipulating layer”, refers to a material adapted to influence a transport of one kind of charge carriers. In particular, the term “charge-carrier transporting layer” refers to a material adapted to facilitate a transport of charge carriers, i.e. electrons or holes, on a way through the material whereas the term “charge-carrier blocking layer” relates to a material adapted to inhibit the transport of the corresponding charge carriers through the respective layer. However, some arrangements may, in general, be equivalent since a layer adapted to inhibit the transport of a specific charge carrier may be capable of achieving a similar effect as a layer adapted to facilitate the transport of the oppositely charged charge carrier. By way of example, instead of using a hole transporting layer an electron blocking layer may, alternatively, be employed to accomplish the same effect.

In a particularly preferred embodiment, the charge-carrier blocking layer may be a hole blocking layer. Herein, the hole blocking layer may, preferably, comprise at least one of:
a carbonate, in particular cesium carbonate (Cs₂CO₃),
polyethylenimine (PEI),
polyethylenimine ethoxylated (PEIE),
2,9-dimethyl-4,7-diphenylphenanthroline (BCP),
(3-(4-biphenylyl)-4-phenyl-5-(4-tert-butylphenyl)-1,2,4-triazole) (TAZ),
   a transition metal oxide, in particular zinc oxide (ZnO) or titanium dioxide (TiO₂), or
   an alkaline fluoride, in particular lithium fluoride (LiF) or sodium fluoride (NaF).

In this particularly preferred embodiment, the charge-carrier transporting layer may, accordingly, be a hole transporting layer being designated to selectively transport holes. Herein, the hole transporting layer may, preferably, be selected from the group consisting of:
a poly-3,4-ethylenedioxythiophene (PEDOT), preferably PEDOT electrically doped with at least one counter ion, more preferably PEDOT doped with sodium polystyrene sulfonate (PEDOT:PSS);
a polyaniline (PANI);
a sulfonated tetrafluoroethylene-based fluoropolymer-copolymer (Nafion); and
a polythiophene (PT).

As mentioned above, instead of using a hole transporting layer an electron blocking layer may, alternatively, be employed here, wherein the electron blocking layer may be designated to block electrons from being transported, such as by alignment of the work functions or by forming of a dipole layer. In particular, the electron blocking layer may, preferably, be selected from the group consisting of:
a molybdenum oxide, usually denoted by MoO₃; and
a nickel oxide, such as NiO, Ni₂O₃, a modification, or a mixture thereof.

However, other kinds of materials and combinations of these materials among themselves and/or with other of the mentioned materials may also be applicable. In addition, one or more further layers comprising the same or additional material which may be adapted for one or more specific purposes, may also be employed.

For the purpose of facilitating a production of the transversal optical sensor according to the present invention, the charge-carrier blocking layer and/or the charge-carrier transporting layer may be provided by using a deposition method, preferably by a coating method, more preferred by a spin-coating method, a slot-coating method, a blade-coating method, or, alternatively, by evaporation. Thus, the resulting layer may, preferably, be a spin-cast layer, a slot-coated layer, or a blade-coated layer. Further, as mentioned above, one or more of the cover layers within the transversal optical sensor may be provided as thin layers on a corresponding substrate. For this purpose, the respective material may also be deposited onto the corresponding substrate by using a suitable deposition method, such as a coating or evaporation method.

As used herein, the term “evaluation device” generally refers to an arbitrary device designed to generate the items of information, i.e. the at least one item of information on the position of the object, in particular on the lateral position of the object. As an example, the evaluation device may be or may comprise one or more integrated circuits, such as one or more application-specific integrated circuits (ASICs), and/or one or more data processing devices, such as one or more computers, preferably one or more microcomputers and/or microcontrollers. Additional components may be comprised, such as one or more preprocessing devices and/or data acquisition devices, such as one or more devices for receiving and/or preprocessing of the sensor signals, such as one or more AD-converters and/or one or more filters. As used herein, the sensor signal may generally refer to one of the transversal sensor signals and, if applicable, to the transversal sensor signal. Further, the evaluation device may comprise one or more data storage devices. Further, as outlined above, the evaluation device may comprise one or more interfaces, such as one or more wireless interfaces and/or one or more wire-bound interfaces.

The at least one evaluation device may be adapted to perform at least one computer program, such as at least one computer program performing or supporting the step of generating the items of information. As an example, one or more algorithms may be implemented which, by using the sensor signals as input variables, may perform a predetermined transformation into the position of the object.

The evaluation device may particularly comprise at least one data processing device, in particular an electronic data processing device, which can be designed to generate the items of information by evaluating the sensor signals. Thus, the evaluation device is designed to use the sensor signals as input variables and to generate the items of information on the transversal position and, as described below in more detail, the longitudinal position of the object by processing these input variables. The processing can be done in parallel, subsequently or even in a combined manner. The evaluation device may use an arbitrary process for generating these items of information, such as by calculation and/or using at least one stored and/or known relationship. Besides the sensor signals, one or a plurality of further parameters and/or items of information can influence said relationship, for example at least one item of information about a modulation frequency. The relationship can be determined or determinable empirically, analytically or else semi-empirically. Particularly preferably, the relationship comprises at least one calibration curve, at least one set of calibration curves, at least one function or a combination of the possibilities mentioned. One or a plurality of calibration curves can be stored for example in the form of a set of values and the associated function values thereof, for example in a data storage device and/or a table. Alternatively or additionally, however, the at least one calibration curve can also be stored for example in parameterized form and/or as a functional equation. Separate relationships for processing the sensor signals into the items of information may be used. Alternatively, at least one combined relationship for processing the sensor signals is feasible. Various possibilities are conceivable and can also be combined.

By way of example, the evaluation device can be designed in terms of programming for the purpose of determining the items of information. The evaluation device can comprise in particular at least one computer, for example at least one microcomputer. Furthermore, the evaluation device can comprise one or a plurality of volatile or nonvolatile data memories. As an alternative or in addition to a data processing device, in particular at least one computer, the evaluation device can comprise one or a plurality of further electronic components which are designed for determining the items of information, for example an electronic table and in particular at least one look-up table and/or at least one application-specific integrated circuit (ASIC).

The detector has, as described above, at least one evaluation device. In particular, the at least one evaluation device can also be designed to completely or partly control or drive the detector, for example by the evaluation device being designed to control at least one illumination source and/or to control at least one modulation device of the detector. The evaluation device can be designed, in particular, to carry out at least one measurement cycle in which one or a plurality of sensor signals, such as a plurality of sensor signals, are picked up, for example a plurality of sensor signals of successively at different modulation frequencies of the illumination.

The evaluation device is designed, as described above, to generate at least one item of information on the position of the object by evaluating the at least one sensor signal. Said position of the object can be static or may even comprise at least one movement of the object, for example a relative movement between the detector or parts thereof and the object or parts thereof. In this case, a relative movement can generally comprise at least one linear movement and/or at least one rotational movement. Items of movement information can for example also be obtained by comparison of at least two items of information picked up at different times, such that for example at least one item of location information can also comprise at least one item of velocity information and/or at least one item of acceleration information, for example at least one item of information about at least one relative velocity between the object or parts thereof and the detector or parts thereof. In particular, the at least one item of location information can generally be selected from: an item of information about a distance between the object or parts thereof and the detector or parts thereof, in particular an optical path length; an item of information about a distance or an optical distance between the object or parts thereof and the optional transfer device or parts thereof; an item of information about a positioning of the object or parts thereof relative to the detector or parts thereof; an item of information about an orientation of the object and/or parts thereof relative to the detector or parts thereof; an item of information about a relative movement between the object or parts thereof and the detector or parts thereof; an item of information about a two-dimensional or three-dimensional spatial configuration of the object or of parts thereof, in particular a geometry or form of the object. Generally, the at least one item of location information can therefore be selected for example from the group consisting of: an item of information about at least one location of the object or at least one part thereof; information about at least one orientation of the object or a part thereof; an item of information about a geometry or form of the object or of a part thereof, an item of information about a velocity of the object or of a part thereof, an item of information about an acceleration of the object or of a part thereof, an item of information about a presence or absence of the object or of a part thereof in a visual range of the detector. The at least one item of location information can be specified for example in at least one coordinate system, for example a coordinate system in which the detector or parts thereof rest. Alternatively or additionally, the location information can also simply comprise for example a distance between the detector or parts thereof and the object or parts thereof. Combinations of the possibilities mentioned are also conceivable.

Herein, some of the mentioned information may be determined by using only at least one lateral detector optical sensor according to the present invention whereas acquiring other information may require, additionally, at least one longitudinal optical sensor. Thus, as used herein, the term “longitudinal optical sensor” may, generally, refer to a device which is designed to generate at least one longitudinal sensor signal in a manner dependent on an illumination of the sensor region by the light beam, wherein the longitudinal sensor signal, given the same total power of the illumination, is dependent, according to the so-called “FIP effect”, on a beam cross-section of the light beam in the sensor region. The longitudinal sensor signal may generally be an arbitrary signal indicative of the longitudinal position of the object, which may also be denoted as a depth.

In a particularly preferred embodiment, the transversal optical sensor according to the present invention may, concurrently, be employed as the longitudinal optical sensor. For this purpose, the evaluation device of the optical detector may, in addition, be designed to generate at least one item of information on a longitudinal position of the object by evaluating the transversal sensor signals of the transversal optical sensor of the present invention in a different manner. The different manner may, thus, comprise treating the transversal sensor signal provided by the transversal optical sensor as a longitudinal sensor signal which, given the same total power of the illumination, is also dependent, according to the so-called “FIP effect”, on the beam cross-section of the light beam within the sensor region. Consequently, the transversal sensor signal may, thus, also be considered as being indicative of the longitudinal position of the object, also denoted by the term “depth”. By way of example, as described in a particular embodiment of WO 2016/120392 A1, the sensor region of the longitudinal optical sensor may comprise at least one photoconductive material, thus, allowing the concurrent use of the transversal optical sensor according to the present invention as the longitudinal optical sensor. For further potential embodiments of the longitudinal optical sensor and for further details concerning the evaluation of the sensor signals, reference may be made to the description of the longitudinal optical sensors as, for example, disclosed in WO 2012/110924 A1, WO 2014/097181 A1, or WO 2016/120392 A1.

Further, as disclosed in WO 2014/097181 A1, the detector according to the present invention may comprise more than one optical sensor, in particular, one or more transversal optical sensors in combination with one or more longitudinal optical sensors, in particular, a stack of longitudinal optical sensors. As an example, one or more transversal optical sensors may be located on a side of the stack of longitudinal optical sensors facing towards the object. Alternatively or additionally, one or more transversal optical sensors may be located on a side of the stack of longitudinal optical sensors facing away from the object. Again, additionally or alternatively, one or more transversal optical sensors may be interposed in between the longitudinal optical sensors of the stack. However, embodiments which may only comprise a single transversal optical sensor but no longitudinal optical sensor may still be possible, such as in a case wherein only determining one or more lateral dimensions of the object may be desired.

Accordingly, the detector may comprise at least two optical sensors, wherein each optical sensor may be adapted to generate at least one sensor signal. As an example, the sensor surfaces of the optical sensors may, thus, be oriented in parallel, wherein slight angular tolerances might be tolerable, such as angular tolerances of no more than 10°, preferably of no more than 5°. Herein, preferably all of the optical sensors of the detector, which may, preferably, be arranged in form of a stack along the optical axis of the detector, may be transparent. Thus, the light beam may pass through a first transparent optical sensor before impinging on the other optical sensors, preferably subsequently. Thus, the light beam from the object may subsequently reach all optical sensors present in the optical detector. For this purpose, the last optical sensor, i.e. the optical sensor which is finally impinged by the incident light beam, may also be intransparent. Herein, the different optical sensors may exhibit the same or different spectral sensitivities with respect to the incident light beam.

Further embodiments of the present invention may refer to the nature of the light beam which may propagate from the object to the detector. As used herein, the term “light” generally refers to electromagnetic radiation in one or more of the visible spectral range, the ultraviolet spectral range and the infrared spectral range. Therein, in partial accordance with standard ISO-21348 in a valid version at the date of this application, the term “visible spectral range” (Vis) generally refers to a spectral range of 380 nm to 760 nm. The term “ultraviolet spectral range” (UV) generally refers to electromagnetic radiation of 1 nm to 380 nm, preferably of 100 nm to 380 nm. The term “infrared spectral range” (IR) generally refers to electromagnetic radiation of 760 nm to 1000 μm, wherein the range of 760 nm to 1.5 μm is usually denominated as “near infrared spectral range” (NIR), the range of 1.5 μm to 15 μm as “mid infrared spectral range” (MidIR), and the range of 15 μm to 1000 μm as “far infrared spectral range” (FIR). Preferably, light used for the present invention is in the Vis, NIR and/or MidIR range, in particular of 380 nm to 3000 nm.

The term “light beam” generally refers to an amount of light emitted into a specific direction. Thus, the light beam may be a bundle of the light rays having a predetermined extension in a direction perpendicular to a direction of propagation of the light beam. Preferably, the light beam may be or may comprise one or more Gaussian light beams which may be characterized by one or more Gaussian beam parameters, such as one or more of a beam waist, a Rayleigh-length or any other beam parameter or combination of beam parameters suited to characterize a development of a beam diameter and/or a beam propagation in space.

The light beam might be admitted by the object itself, i.e. might originate from the object. Additionally or alternatively, another origin of the light beam is feasible. Thus, as will be outlined in further detail below, one or more illumination sources might be provided which illuminate the object, such as by using one or more primary rays or beams, such as one or more primary rays or beams having a predetermined characteristic. In the latter case, the light beam propagating from the object to the detector might be a light beam which is reflected by the object and/or a reflection device connected to the object.

In addition, the detector may comprise at least one transfer device, such as an optical lens, in particular one or more refractive lenses, particularly converging thin refractive lenses, such as convex or biconvex thin lenses, and/or one or more convex mirrors, which may further be arranged along the common optical axis. Most preferably, the light beam which emerges from the object may in this case travel first through the at least one transfer device and thereafter through the at least one transparent transversal optical sensor until it may finally impinge on an imaging device. As used herein, the term “transfer device” refers to an optical element which may be configured to transfer the at least one light beam emerging from the object to optical sensors within the detector, i.e. the at least one transversal optical sensor and the at least one optional longitudinal optical sensor. Thus, the transfer device can be designed to feed light propagating from the object to the detector to the optical sensors, wherein this feeding can optionally be effected by means of imaging or else by means of non-imaging properties of the transfer device. In particular the transfer device can also be designed to collect the electromagnetic radiation before the latter is fed to the transversal optical sensor and/or, if applicable, to the optional longitudinal optical sensor.

In addition, the at least one transfer device may have imaging properties. Consequently, the transfer device comprises at least one imaging element, for example at least one lens and/or at least one curved mirror, since, in the case of such imaging elements, for example, a geometry of the illumination on the sensor region can be dependent on a relative positioning, for example a distance, between the transfer device and the object. As used herein, the transfer device may be designed in such a way that the electromagnetic radiation which emerges from the object is transferred completely to the sensor region, for example is focused completely onto the optical sensor, in particular if the object is arranged in a visual range of the detector.

Generally, the detector may further comprise at least one imaging device, i.e. a device capable of acquiring at least one image. The imaging device can be embodied in various ways. Thus, the imaging device can be for example part of the detector in a detector housing. Alternatively or additionally, however, the imaging device can also be arranged outside the detector housing, for example as a separate imaging device. Alternatively or additionally, the imaging device can also be connected to the detector or even be part of the detector. In a preferred arrangement, the at least one optical sensor and the imaging device are aligned along a common optical axis along which the light beam travels. Thus, it may be possible to locate an imaging device in the optical path of the light beam in a manner that the light beam travels through the at least one optical sensor until it impinges on the imaging device. However, other arrangements are possible.

As used herein, an “imaging device” is generally understood as a device which can generate a one-dimensional, a two-dimensional, or a three-dimensional image of the object or of a part thereof. In particular, the detector, with or without the at least one optional imaging device, can be completely or partly used as a camera, such as an IR camera, or an RGB camera, i.e. a camera which is designed to deliver three basic colors which are designated as red, green, and blue, on three separate connections. Thus, as an example, the at least one imaging device may be or may comprise at least one imaging device selected from the group consisting of: a pixelated organic camera element, preferably a pixelated organic camera chip; a pixelated inorganic camera element, preferably a pixelated inorganic camera chip, more preferably a CCD- or CMOS-chip; a monochrome camera element, preferably a monochrome camera chip; a multicolor camera element, preferably a multicolor camera chip; a full-color camera element, preferably a full-color camera chip. The imaging device may be or may comprise at least one device selected from the group consisting of a monochrome imaging device, a multi-chrome imaging device and at least one full color imaging device. A multi-chrome imaging device and/or a full color imaging device may be generated by using filter techniques and/or by using intrinsic color sensitivity or other techniques, as the skilled person will recognize. Other embodiments of the imaging device are also possible.

The imaging device may be designed to image a plurality of partial regions of the object successively and/or simultaneously. By way of example, a partial region of the object can be a one-dimensional, a two-dimensional, or a three-dimensional region of the object which is delimited for example by a resolution limit of the imaging device and from which electromagnetic radiation emerges. In this context, imaging should be understood to mean that the electromagnetic radiation which emerges from the respective partial region of the object is fed into the imaging device, for example by means of the at least one optional transfer device of the detector. The electromagnetic rays can be generated by the object itself, for example in the form of a luminescent radiation. Alternatively or additionally, the at least one detector may comprise at least one illumination source for illuminating the object.

In particular, the imaging device can be designed to image sequentially, for example by means of a scanning method, in particular using at least one row scan and/or line scan, the plurality of partial regions sequentially. However, other embodiments are also possible, for example embodiments in which a plurality of partial regions is simultaneously imaged. The imaging device is designed to generate, during this imaging of the partial regions of the object, signals, preferably electronic signals, associated with the partial regions. The signal may be an analogue and/or a digital signal. By way of example, an electronic signal can be associated with each partial region. The electronic signals can accordingly be generated simultaneously or else in a temporally staggered manner. By way of example, during a row scan or line scan, it is possible to generate a sequence of electronic signals which correspond to the partial regions of the object, which are strung together in a line, for example. Further, the imaging device may comprise one or more signal processing devices, such as one or more filters and/or analogue-digital-converters for processing and/or preprocessing the electronic signals.

Light emerging from the object can originate in the object itself, but can also optionally have a different origin and propagate from this origin to the object and subsequently toward the optical sensors. The latter case can be affected for example by at least one illumination source being used. The illumination source can be embodied in various ways. Thus, the illumination source can be for example part of the detector in a detector housing. Alternatively or additionally, however, the at least one illumination source can also be arranged outside a detector housing, for example as a separate light source. The illumination source can be arranged separately from the object and illuminate the object from a distance. Alternatively or additionally, the illumination source can also be connected to the object or even be part of the object, such that, by way of example, the electromagnetic radiation emerging from the object can also be generated directly by the illumination source. By way of example, at least one illumination source can be arranged on and/or in the object and directly generate the electromagnetic radiation by means of which the sensor region is illuminated. This illumination source can for example be or comprise an ambient light source and/or may be or may comprise an artificial illumination source. By way of example, at least one infrared emitter and/or at least one emitter for visible light and/or at least one emitter for ultraviolet light can be arranged on the object. By way of example, at least one light emitting diode and/or at least one laser diode can be arranged on and/or in the object. The illumination source can comprise in particular one or a plurality of the following illumination sources: a laser, in particular a laser diode, although in principle, alternatively or additionally, other types of lasers can also be used; a light emitting diode; an incandescent lamp; a neon light; a flame source; a heat source; an organic light source, in particular an organic light emitting diode; a structured light source. Alternatively or additionally, other illumination sources can also be used. It is particularly preferred if the illumination source is designed to generate one or more light beams having a Gaussian beam profile, as is at least approximately the case for example in many lasers. For further potential embodiments of the optional illumination source, reference may be made to one of WO 2012/110924 A1 and WO 2014/097181 A1. Still, other embodiments are feasible.

The at least one optional illumination source generally may emit light in at least one of: the ultraviolet spectral range, preferably of 100 nm to 380 nm; the visible spectral range of 380 nm to 760 nm; the infrared spectral range of 760 nm to 1000 μm. Herein, it is particularly preferred when the illumination source may exhibit a spectral range being related to the spectral sensitivities of the transversal optical sensors, in particular, to ensure that the transversal optical sensor illuminated by the respective illumination source may provide a sensor signal with a high intensity, thus, enabling a high-resolution evaluation with a sufficient signal-to-noise-ratio.

Irrespective of the actual configuration of this preferred embodiment, a comparatively simple and cost-efficient setup for the transversal optical sensor may be obtained, wherein the transversal optical sensor may comprise at least partially transparent optical properties and may, in addition, exhibit a comparatively high sensitivity within the visible and/or infrared (IR) spectral ranges, preferably in a range of 380 nm to 3000 nm. Thus, the setup for the transversal optical sensor according to the present invention may, in particular, allow using this kind of transversal optical sensor as a position sensitive device. However, other embodiments may also be appropriate.

Furthermore, the detector can have at least one modulation device for modulating the illumination, in particular for a periodic modulation, in particular a periodic beam interrupting device. A modulation of the illumination should be understood to mean a process in which a total power of the illumination is varied, preferably periodically, in particular with one or a plurality of modulation frequencies. In particular, a periodic modulation can be effected between a maximum value and a minimum value of the total power of the illumination. The minimum value can be 0, but can also be >0, such that, by way of example, complete modulation does not have to be effected. The modulation can be effected for example in a beam path between the object and the optical sensor, for example by the at least one modulation device being arranged in said beam path. Alternatively or additionally, however, the modulation can also be effected in a beam path between an optional illumination source—described in even greater detail below—for illuminating the object and the object, for example by the at least one modulation device being arranged in said beam path. A combination of these possibilities is also conceivable. The at least one modulation device can comprise for example a beam chopper or some other type of periodic beam interrupting device, for example comprising at least one interrupter blade or interrupter wheel, which preferably rotates at constant speed and which can thus periodically interrupt the illumination. Alternatively or additionally, however, it is also possible to use one or a plurality of different types of modulation devices, for example modulation devices based on an electro-optical effect and/or an acousto-optical effect. Once again alternatively or additionally, the at least one optional illumination source itself can also be designed to generate a modulated illumination, e.g. by said illumination source itself having a modulated intensity and/or total power, e.g. a periodically modulated total power, and/or by said illumination source being embodied as a pulsed illumination source, for example as a pulsed laser. Thus, by way of example, the at least one modulation device can also be wholly or partly integrated into the illumination source. Various possibilities are conceivable.

Accordingly, the detector can be designed in particular to detect at least two transversal sensor signals in the case of different modulations, in particular at least two transversal sensor signals at respectively different modulation frequencies. As a result, the two different transversal sensor signals may, thus, be distinguishable, by their respectively different modulation frequencies. The evaluation device can be designed to generate the geometrical information from the at least two transversal sensor signals. By way of example, the detector can be designed to bring about a modulation of the illumination of the object and/or at least the transversal optical sensor with a frequency of 0.05 Hz to 1 MHz, such as 0.1 Hz to 10 kHz. As outlined above, for this purpose, the detector may comprise at least one modulation device, which may be integrated into the at least one optional illumination source and/or may be independent from the illumination source. Thus, at least one illumination source might, by itself, be adapted to generate the above-mentioned modulation of the illumination, and/or at least one independent modulation device may be present, such as at least one chopper and/or at least one device having a modulated transmissibility, such as at least one electro-optical device and/or at least one acousto-optical device.

In a further aspect of the present invention, a human-machine interface for exchanging at least one item of information between a user and a machine is proposed. The human-machine interface as proposed may make use of the fact that the above-mentioned detector in one or more of the embodiments mentioned above or as mentioned in further detail below may be used by one or more users for providing information and/or commands to a machine. Thus, preferably, the human-machine interface may be used for inputting control commands.

The human-machine interface comprises at least one detector according to the present invention, such as according to one or more of the embodiments disclosed above and/or according to one or more of the embodiments as disclosed in further detail below, wherein the human-machine interface is designed to generate at least one item of geometrical information of the user by means of the detector wherein the human-machine interface is designed to assign the geometrical information to at least one item of information, in particular to at least one control command.

In a further aspect of the present invention, an entertainment device for carrying out at least one entertainment function is disclosed. As used herein, an entertainment device is a device which may serve the purpose of leisure and/or entertainment of one or more users, in the following also referred to as one or more players. As an example, the entertainment device may serve the purpose of gaming, preferably computer gaming. Additionally or alternatively, the entertainment device may also be used for other purposes, such as for exercising, sports, physical therapy or motion tracking in general. Thus, the entertainment device may be implemented into a computer, a computer network or a computer system or may comprise a computer, a computer network or a computer system which runs one or more gaming software programs.

The entertainment device comprises at least one human-machine interface according to the present invention, such as according to one or more of the embodiments disclosed above and/or according to one or more of the embodiments disclosed below. The entertainment device is designed to enable at least one item of information to be input by a player by means of the human-machine interface. The at least one item of information may be transmitted to and/or may be used by a controller and/or a computer of the entertainment device.

In a further aspect of the present invention, a tracking system for tracking the position of at least one movable object is provided. As used herein, a tracking system is a device which is adapted to gather information on a series of past positions of the at least one object or at least one part of an object. Additionally, the tracking system may be adapted to provide information on at least one predicted future position of the at least one object or the at least one part of the object. The tracking system may have at least one track controller, which may fully or partially be embodied as an electronic device, preferably as at least one data processing device, more preferably as at least one computer or microcontroller. Again, the at least one track controller may comprise the at least one evaluation device and/or may be part of the at least one evaluation device and/or might fully or partially be identical to the at least one evaluation device.

The tracking system comprises at least one detector according to the present invention, such as at least one detector as disclosed in one or more of the embodiments listed above and/or as disclosed in one or more of the embodiments below. The tracking system further comprises at least one track controller. The tracking system may comprise one, two or more detectors, particularly two or more identical detectors, which allow for a reliable acquisition of depth information about the at least one object in an overlapping volume between the two or more detectors. The track controller is adapted to track a series of positions of the object, each position comprising at least one item of information on a position of the object at a specific point in time.

The tracking system may further comprise at least one beacon device connectable to the object. For a potential definition of the beacon device, reference may be made to WO 2014/097181 A1. The tracking system preferably is adapted such that the detector may generate an information on the position of the object of the at least one beacon device, in particular to generate the information on the position of the object which comprises a specific beacon device exhibiting a specific spectral sensitivity. Thus, more than one beacon exhibiting a different spectral sensitivity may be tracked by the detector of the present invention, preferably in a simultaneous manner. Herein, the beacon device may fully or partially be embodied as an active beacon device and/or as a passive beacon device. As an example, the beacon device may comprise at least one illumination source adapted to generate at least one light beam to be transmitted to the detector. Additionally or alternatively, the beacon device may comprise at least one reflector adapted to reflect light generated by an illumination source, thereby generating a reflected light beam to be transmitted to the detector.

In a further aspect of the present invention, a scanning system for determining at least one position of at least one object is provided. As used herein, the scanning system is a device which is adapted to emit at least one light beam being configured for an illumination of at least one dot located at at least one surface of the at least one object and for generating at least one item of information about the distance between the at least one dot and the scanning system. For the purpose of generating the at least one item of information about the distance between the at least one dot and the scanning system, the scanning system comprises at least one of the detectors according to the present invention, such as at least one of the detectors as disclosed in one or more of the embodiments listed above and/or as disclosed in one or more of the embodiments below.

Thus, the scanning system comprises at least one illumination source which is adapted to emit the at least one light beam being configured for the illumination of the at least one dot located at the at least one surface of the at least one object. As used herein, the term “dot” refers to a small area on a part of the surface of the object which may be selected, for example by a user of the scanning system, to be illuminated by the illumination source. Preferably, the dot may exhibit a size which may, on one hand, be as small as possible in order to allow the scanning system determining a value for the distance between the illumination source comprised by the scanning system and the part of the surface of the object on which the dot may be located as exactly as possible and which, on the other hand, may be as large as possible in order to allow the user of the scanning system or the scanning system itself, in particular by an automatic procedure, to detect a presence of the dot on the related part of the surface of the object.

For this purpose, the illumination source may comprise an artificial illumination source, in particular at least one laser source and/or at least one incandescent lamp and/or at least one semiconductor light source, for example, at least one light-emitting diode, in particular an organic and/or inorganic light-emitting diode. On account of their generally defined beam profiles and other properties of handleability, the use of at least one laser source as the illumination source is particularly preferred. Herein, the use of a single laser source may be preferred, in particular in a case in which it may be important to provide a compact scanning system that might be easily storable and transportable by the user. The illumination source may thus, preferably be a constituent part of the detector and may, therefore, in particular be integrated into the detector, such as into the housing of the detector. In a preferred embodiment, particularly the housing of the scanning system may comprise at least one display configured for providing distance-related information to the user, such as in an easy-to-read manner. In a further preferred embodiment, particularly the housing of the scanning system may, in addition, comprise at least one button which may be configured for operating at least one function related to the scanning system, such as for setting one or more operation modes. In a further preferred embodiment, particularly the housing of the scanning system may, in addition, comprise at least one fastening unit which may be configured for fastening the scanning system to a further surface, such as a rubber foot, a base plate or a wall holder, such comprising as magnetic material, in particular for increasing the accuracy of the distance measurement and/or the handleability of the scanning system by the user.

In a particularly preferred embodiment, the illumination source of the scanning system may, thus, emit a single laser beam which may be configured for the illumination of a single dot located at the surface of the object. By using at least one of the detectors according to the present invention at least one item of information about the distance between the at least one dot and the scanning system may, thus, be generated. Hereby, preferably, the distance between the illumination system as comprised by the scanning system and the single dot as generated by the illumination source may be determined, such as by employing the evaluation device as comprised by the at least one detector. However, the scanning system may, further, comprise an additional evaluation system which may, particularly, be adapted for this purpose. Alternatively or in addition, a size of the scanning system, in particular of the housing of the scanning system, may be taken into account and, thus, the distance between a specific point on the housing of the scanning system, such as a front edge or a back edge of the housing, and the single dot may, alternatively, be determined.

Alternatively, the illumination source of the scanning system may emit two individual laser beams which may be configured for providing a respective angle, such as a right angle, between the directions of an emission of the beams, whereby two respective dots located at the surface of the same object or at two different surfaces at two separate objects may be illuminated. However, other values for the respective angle between the two individual laser beams may also be feasible. This feature may, in particular, be employed for indirect measuring functions, such as for deriving an indirect distance which may not be directly accessible, such as due to a presence of one or more obstacles between the scanning system and the dot or which may otherwise be hard to reach. By way of example, it may, thus, be feasible to determine a value for a height of an object by measuring two individual distances and deriving the height by using the Pythagoras formula. In particular for being able to keep a predefined level with respect to the object, the scanning system may, further, comprise at least one leveling unit, in particular an integrated bubble vial, which may be used for keeping the predefined level by the user.

As a further alternative, the illumination source of the scanning system may emit a plurality of individual laser beams, such as an array of laser beams which may exhibit a respective pitch, in particular a regular pitch, with respect to each other and which may be arranged in a manner in order to generate an array of dots located on the at least one surface of the at least one object. For this purpose, specially adapted optical elements, such as beam-splitting devices and mirrors, may be provided which may allow a generation of the described array of the laser beams.

Thus, the scanning system may provide a static arrangement of the one or more dots placed on the one or more surfaces of the one or more objects. Alternatively, illumination source of the scanning system, in particular the one or more laser beams, such as the above described array of the laser beams, may be configured for providing one or more light beams which may exhibit a varying intensity over time and/or which may be subject to an alternating direction of emission in a passage of time. Thus, the illumination source may be configured for scanning a part of the at least one surface of the at least one object as an image by using one or more light beams with alternating features as generated by the at least one illumination source of the scanning device. In particular, the scanning system may, thus, use at least one row scan and/or line scan, such as to scan the one or more surfaces of the one or more objects sequentially or simultaneously.

In a further aspect of the present invention, a camera for imaging at least one object is disclosed. The camera comprises at least one detector according to the present invention, such as disclosed in one or more of the embodiments given above or given in further detail below. In a particularly preferred embodiment, the camera may comprise at least one transversal optical detector according to the present invention together with at least one longitudinal optical sensor, such as described in WO 2012/110924 A1, WO 2014/097181 A1, or WO 2016/120392 A1. Thus, the detector may be part of a photographic device, specifically of a digital camera. Specifically, the detector may be used in 3D photography, specifically in digital 3D photography. Thus, the detector may be part of a digital 3D camera. As used herein, the term “photography” generally refers to the technology of acquiring image information of at least one object. As further used herein, a “camera” generally is a device adapted for performing photography. As further used herein, the term “digital photography” generally refers to the technology of acquiring image information of at least one object by using a plurality of light-sensitive elements adapted to generate electrical signals indicating an intensity of illumination, preferably digital electrical signals. As further used herein, the term “3D photography” generally refers to the technology of acquiring image information of at least one object in three spatial dimensions. Accordingly, a 3D camera is a device adapted for performing 3D photography. The camera generally may be adapted for acquiring a single image, such as a single 3D image, or may be adapted for acquiring a plurality of images, such as a sequence of images. Thus, the camera may also be a video camera adapted for video applications, such as for acquiring digital video sequences.

Thus, generally, the present invention further refers to a camera, specifically a digital camera, more specifically a 3D camera or digital 3D camera, for imaging at least one object. As outlined above, the term “imaging”, as used herein, generally refers to acquiring image information of at least one object. The camera comprises at least one detector according to the present invention. The camera, as outlined above, may be adapted for acquiring a single image or for acquiring a plurality of images, such as image sequence, preferably for acquiring digital video sequences. Thus, as an example, the camera may be or may comprise a video camera. In the latter case, the camera preferably comprises a data memory for storing the image sequence. In a further aspect of the present invention, a method for determining a position of at least one object is disclosed. The method preferably may make use of at least one detector according to the present invention, such as of at least one detector according to one or more of the embodiments disclosed above or disclosed in further detail below. Thus, for optional embodiments of the method, reference might be made to the description of the various embodiments of the detector.

The method comprises the following steps, which may be performed in the given order or in a different order. Further, additional method steps might be provided which are not listed. Further, two or more or even all of the method steps might be performed simultaneously, at least partially. Further, two or more or even all of the method steps might be performed twice or even more than twice, repeatedly.

The method according to the present invention comprises the following steps:
generating at least one transversal sensor signal by using at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photosensitive layer embedded between at least two conductive layers, wherein at least one of the conductive layers comprises an at least partially transparent graphene layer on an at least partially transparent substrate allowing the light beam to travel to the photosensitive layer, wherein the transversal optical sensor is further adapted to generate at least one transversal sensor signal indicative of indicative of the transversal position of the light beam in the photosensitive layer; and
generating at least one item of information on a transversal position of the object by evaluating the at least one transversal sensor signal.

For further details concerning the method according to the present invention, reference may be made to the description of the optical detector as provided above and/or below.

In a further aspect of the present invention, a use of a detector according to the present invention is disclosed. Therein, a use of the detector for a purpose of determining a position of an object, in particular a lateral position of an object, is proposed, wherein the detector may, preferably, be used concurrently as at least one longitudinal optical sensor or combined with at least one additional longitudinal optical sensor, in particular, for a purpose of use selected from the group consisting of: a position measurement, in particular in traffic technology; an entertainment application; a security application; a human-machine interface application; a tracking application; a scanning application; a stereoscopic vision application; a photography application; an imaging application or camera application; a mapping application for generating maps of at least one space; a homing or tracking beacon detector for vehicles; a position measurement of objects with a thermal signature (hotter or colder than background); a machine vision application; a robotic application.

Further uses of the optical detector according to the present invention may also refer to combinations with applications already been known, such as determining the presence or absence of an object; extending optical applications, e.g. camera exposure control, auto slide focus, automated rear view mirrors, electronic scales, automatic gain control, particularly in modulated light sources, automatic headlight dimmers, night (street) light controls, oil burner flame outs, or smoke detectors; or other applications, such as in densitometers, e.g. determining the density of toner in photocopy machines; or in colorimetric measurements.

Thus, generally, the devices according to the present invention, such as the detector, may be applied in various fields of uses. Specifically, the detector may be applied for a purpose of use, selected from the group consisting of: a position measurement in traffic technology; an entertainment application; a security application; a human-machine interface application; a tracking application; a photography application; a cartography application; a mapping application for generating maps of at least one space; a homing or tracking beacon detector for vehicles; a mobile application; a webcam; an audio device; a Dolby surround audio system; a computer peripheral device; a gaming application; a camera or video application; a surveillance application; an automotive application; a transport application; a logistics application; a vehicle application; an airplane application; a ship application; a spacecraft application; a robotic application; a medical application; a sports' application; a building application; a construction application; a manufacturing application; a machine vision application; a use in combination with at least one sensing technology selected from time-of-flight detector, radar, Lidar, ultrasonic sensors, or interferometry. Additionally or alternatively, applications in local and/or global positioning systems may be named, especially landmark-based positioning and/or navigation, specifically for use in cars or other vehicles (such as trains, motorcycles, bicycles, trucks for cargo transportation), robots or for use by pedestrians. Further, indoor positioning systems may be named as potential applications, such as for household applications and/or for robots used in manufacturing, logistics, surveillance, or maintenance technology.

Preferably, for further potential details of the optical detector, the method, the human-machine interface, the entertainment device, the tracking system, the camera and the various uses of the detector, in particular with regard to the transfer device, the transversal optical sensors, the evaluation device and, if applicable, to the longitudinal optical sensor, the modulation device, the illumination source and the imaging device, specifically with respect to the potential materials, setups and further details, reference may be made to one or more of WO 2012/110924 A1, US 2012/206336 A1, WO 2014/097181 A1, US 2014/291480 A1, WO 2016/120392 A1, and WO 2017/182432 A1, the full content of all of which is herewith included by reference.

The above-described detector, the method, the human-machine interface and the entertainment device and also the proposed uses have considerable advantages over the prior art. Thus, generally, a simple and, still, efficient detector for an accurate determining a position of at least one object in space may be provided. Therein, as an example, three-dimensional coordinates of an object or a part thereof may be determined in a fast and efficient way.

As compared to devices known in the art, the detector as proposed provides a high degree of simplicity, specifically with regard to an optical setup of the detector. Thus, in principle, using graphene as a transparent conducting material suitable for both the visible and the infrared (IR) spectral ranges, in particular, for wavelengths of 380 nm to 3000 nm, deposited on a substrate which may equally be transparent within at least the mentioned spectral range, thus, allows providing a position sensitive device (PSD) which may, in particular, be applicable for this kind of measurements in the spectral range of 1 μm to 3 μm. This high degree of simplicity, in combination with the possibility of high precision measurements, is specifically suited for machine control, such as in human-machine interfaces and, more preferably, in gaming, tracking, scanning, and a stereoscopic vision. Thus, cost-efficient entertainment devices may be provided which may be used for a large number of gaming, entertaining, tracking, scanning, and stereoscopic vision purposes.

Summarizing, in the context of the present invention, the following embodiments are regarded as particularly preferred:

### EMBODIMENT 1

A detector for an optical detection of at least one object, comprising:
at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photosensitive layer embedded between at least two conductive layers, wherein at least one of the conductive layers comprises an at least partially transparent graphene layer deposited on an at least partially transparent substrate allowing the light beam to travel to the photosensitive layer, wherein the transversal optical sensor is further adapted to generate at least one transversal sensor signal indicative of the transversal position of the light beam in the photosensitive layer; and
at least one evaluation device, wherein the evaluation device is designed to generate at least one item of information on a transversal position of the object by evaluating the at least one transversal sensor signal.

### EMBODIMENT 2

The detector according to the preceding embodiment, wherein the graphene layer exhibits an electrical sheet resistance of 100 Ω/sq to 20000 Ω/sq, preferably of 100 Ω/sq to 10 000 Ω/sq, more preferred 125 of Ω/sq to 1000 Ω/sq, specifically of 150 of Ω/sq to 500 Ω/Sq.

### EMBODIMENT 3

The detector according to any one of the preceding embodiments, wherein the graphene layer is at least partially transparent in a partition of the visible spectral range of 380 nm to 760 nm and in the infrared spectral range above 760 nm to 1000 μm, in particular in the wavelength range of 380 nm to 15 μm, preferably of 380 nm to 3 μm.

### EMBODIMENT 4

The detector according to any one of the preceding embodiments, wherein the graphene layer exhibits a transmission above 80% in a wavelength range of 1 μm to 3 μm.

### EMBODIMENT 5

The detector according to the preceding embodiment, wherein the substrate carrying the graphene layer is at least partially transparent in a partition of the visible spectral range of 380 nm to 760 nm and/or in the infrared spectral range above 760 nm to 1000 μm, in particular in the wavelength range of 380 nm to 15 μm, preferably of 380 nm to 3 μm.

### EMBODIMENT 6

The detector according to the preceding embodiment, wherein the substrate comprises a material selected from the group consisting of quartz glass, sapphire, fused silica, silicon, germanium, zinc selenide, zinc sulfide, silicon carbide, aluminum oxide, calcium fluoride, magnesium fluoride, sodium chloride, or potassium bromide.

### EMBODIMENT 7

The detector according to any one of the preceding embodiments, wherein the graphene is placed on the substrate via a deposition method, wherein the deposition method is selected from chemical vapor deposition (CVD), mechanical exfoliation, chemically derived graphene, and growth from silicon carbide

### EMBODIMENT 8

The detector according to any one of the preceding embodiments, wherein the photosensitive layer comprises an inorganic photovoltaic material, an organic photovoltaic material, an inorganic photoconductive material, an organic photoconductive material, or a plurality of colloidal quantum dots (CQD) comprising an inorganic photovoltaic material or an inorganic photoconductive material.

### EMBODIMENT 9

The detector according to the preceding embodiment, wherein the inorganic photovoltaic material comprises one or more of a group II-VI compound, a group III-V compound, a group IV element or compound, a combination, a solid solution, or a doped variant thereof.

### EMBODIMENT 10

The detector according to the preceding embodiment, wherein the group II-VI compound is a chalcogenide, wherein the chalcogenide is, preferably, selected from the group consisting of: lead sulfide (PbS), lead selenide (PbSe), lead sulfoselenide (PbSSe), lead telluride (PbTe), copper indium sulfide (CIS), copper indium gallium selenide (CIGS), copper zinc tin sulfide (CZTS), copper zinc tin selenide (CZTSe), copper-zinc-tin sulfur-selenium (CZTSSe), cadmium telluride (CdTe), and a solid solution and/or a doped variant thereof.

### EMBODIMENT 11

The detector according to any one of the two preceding embodiments, wherein the group III-V compound is a pnictogenide, wherein the pnictogenide is, preferably, selected from the group consisting of: indium nitride (InN), gallium nitride (GaN), indium gallium nitride (InGaN), indium phosphide (InP), gallium phosphide (GaP), indium gallium phosphide (InGaP), indium arsenide (InAs), gallium arsenide (GaAs), indium gallium arsenide (InGaAs), indium antimonide (InSb), gallium antimonide (GaSb), indium gallium antimonide (InGaSb), indium gallium phosphide (InGaP), gallium arsenide phosphide (GaAsP), and aluminum gallium phosphide (AIGaP).

### EMBODIMENT 12

The detector according to any one of the five preceding embodiments, wherein the group IV element or compound is selected from a group comprising doped diamond (C), doped silicon (Si), silicon carbide (SiC), silicon germanium (SiGe), and doped germanium (Ge).

### EMBODIMENT 13

The detector according to the preceding embodiment, wherein the group IV element or compound is provided as a crystalline material, a microcrystalline material, or, preferably, an amorphous material.

### EMBODIMENT 14

The detector according to any one of the six preceding embodiments, wherein the organic photovoltaic material is arranged in form of at least one photodiode, the photodiode having at least two electrodes, wherein the organic photovoltaic material is embedded between the electrodes.

### EMBODIMENT 15

The detector according to the preceding embodiment, wherein the organic photovoltaic material comprises at least one electron donor material and at least one electron acceptor material.

### EMBODIMENT 16

The detector according to the preceding embodiment, wherein the electron donor material comprises a donor polymer.

### EMBODIMENT 17

The detector according to the preceding embodiment, wherein the electron donor material comprises an organic donor polymer.

### EMBODIMENT 18

The detector according to the preceding embodiment, wherein the donor polymer comprises a conjugated system, wherein the conjugated system is one or more of cyclic, acyclic, and linear.

### EMBODIMENT 19

The detector according to the preceding embodiment, wherein the organic donor polymer is one of poly(3-hexylthiophene-2,5.diyl) (P3HT), poly[3-(4-n-octyl)phenylthiophene] (POPT), poly[3-10-n-octyl-3-phenothiazine-vinylenethiophene-co-2,5-thiophene] (PTZV-PT), poly[4,8-bis[(2-ethylhexyl)oxy] benzo[1,2-b:4,5-b]dithiophene-2,6-diyl][3-fluoro-2-[(2-ethylhexyhcarbonyl]thieno[3,4-b]thiophenediyl] (PTB7), poly{thiophene-2,5-diyl-alt-[5,6-bis(dodecyloxy)benzo[c][1,2,5]thiadiazole]-4,7-diyl} (PBT-T1), poly[2,6-(4,4-bis-(2-ethylhexyl)-4H-cyclopenta[2,1-b;3,4-b]dithiophene)-alt-4,7(2,1,3-benzothiadiazole)] (PCPDTBT), poly(5,7-bis(4-decanyl-2-thienyl)-thieno(3,4-b)diathiazolethiophene-2,5) (PDDTT), poly[N-9′-heptadecanyl-2,7-carbazole-alt-5,5-(4′,7′-di-2-thienyl-2′,1′,3′-benzothiadiazole)] (PCDTBT), poly[(4,4′-bis(2-ethylhexyhdithieno[3,2-b;2′,3′-a]silole)-2,6-diyl-all-(2,1,3-benzothiadiazole)-4,7-diyl] (PSBTBT), poly[3-phenylhydrazone thiophene] (PPHT), poly[2-methoxy-5-(2-ethylhexyl-oxy)-1,4-phenylenevinylene] (MEH-PPV), poly[2-methoxy-5-(2′-ethylhexyloxy)-1,4-phenylene-1,2-ethenylene-2,5-dimethoxy-1,4-phenylene-1,2-ethenylene] (M3EH-PPV), poly[2-methoxy-5-(3′,7′-dimethyloctyloxy)-1,4-phenylenevinylene] (MDMO-PPV), poly[9,9-di-octylfluorene-co-bis-N,N-4-butylphenyl-bis-N,N-phenyl-1,4-phenylenediamine] (PFB), or a derivative, a modification, or a mixture thereof.

### EMBODIMENT 20

The detector according to any one of the preceding embodiments, wherein the electron acceptor material is a fullerene-based electron acceptor material.

### EMBODIMENT 21

The detector according to the preceding embodiment, wherein the fullerene-based electron acceptor material comprises at least one of [6,6]-phenyl-C61-butyric acid methyl ester (PCBM), [6,6]-Phenyl-C71-butyric acid methyl ester (PC70BM), [6,6]-phenyl C84 butyric acid methyl ester (PC84BM), an indene-C60 bisadduct (ICBA), or a derivative, a modification, or a mixture thereof.

### EMBODIMENT 22

The detector according to any one of the two preceding embodiments, wherein the fullerene-based electron acceptor material comprises a dimer comprising one or two C60 or C70 moieties.

### EMBODIMENT 23

The detector according to the preceding embodiment, wherein the fullerene-based electron acceptor comprises a diphenylmethanofullerene (DPM) moiety comprising one or two attached oligoether (OE) chains (C70-DPM-OE or C70-DPM-OE2, respectively).

### EMBODIMENT 24

The detector according to any one of the preceding embodiments, wherein the electron acceptor material is one or more of tetracyanoquinodimethane (TCNQ), a perylene derivative, or inorganic nanoparticles.

### EMBODIMENT 25

The detector according to any one of the preceding embodiments, wherein the electron acceptor material comprises an acceptor polymer.

### EMBODIMENT 26

The detector according to the preceding embodiment, wherein the acceptor polymer comprises a conjugated polymer based on one or more of a cyanated poly(phenylenevinylene), a benzothiadiazole, a perylene or a naphthalenediimide.

### EMBODIMENT 27

The detector according to the preceding embodiment, wherein the acceptor polymer is selected from one or more of a cyano-poly[phenylenevinylene] (CN-PPV), poly[5-(2-(ethyl hexyloxy)-2-methoxycyanoterephthalyliden] (MEH—CN-PPV), poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV), poly[1,4-dioctyloxyl-p-2,5-dicyanophenylenevinylene] (DOCN-PPV), poly[9,9′-di-octylfluoreneco-benzothiadiazole] (PF8BT), or a derivative, a modification, or a mixture thereof.

### EMBODIMENT 28

The detector according to any one of the preceding embodiments, wherein the electron donor material and the electron acceptor material form a mixture.

### EMBODIMENT 29

The detector according to the preceding embodiment, wherein the mixture comprises the electron donor material and the electron acceptor material in a ratio from 1:100 to 100:1, more preferred from 1:10 to 10:1, in particular of from 1:2 to 2:1.

### EMBODIMENT 30

The detector according to any one of the preceding embodiments, wherein the electron donor material and the electron acceptor material comprise an interpenetrating network of donor and acceptor domains, interfacial areas between the donor and acceptor domains, and percolation pathways connecting the domains to the electrodes.

### EMBODIMENT 31

The detector according to any one of the twenty-two preceding embodiments, wherein the colloidal quantum dots (CQD) are obtainable from a colloidal film comprising the plurality of the quantum dots.

### EMBODIMENT 32

The detector according to the preceding embodiment, wherein the colloidal film comprises sub-micrometer-scale semiconductor crystals dispersed in a continuous phase comprising a medium.

### EMBODIMENT 33

The detector according to the preceding embodiment, wherein the medium comprises at least one nonpolar organic solvent.

### EMBODIMENT 34

The detector according to the preceding embodiment, wherein the nonpolar organic solvent is selected from the group comprising octane, toluene, cyclohexane, n-heptane, benzene, chlorobenzene, acetonitrile, dimethylformamide (DMF), and chloroform.

### EMBODIMENT 35

The detector according to any one of the three preceding embodiments, wherein the sub-micrometer-scale semiconductor crystals are, additionally, capped with cross-linking molecules, wherein the cross-linking molecules comprise an organic agent.

### EMBODIMENT 36

The detector according to the preceding embodiment, wherein the organic agent is selected from the group comprising thioles and amines.

### EMBODIMENT 37

The detector according to the preceding embodiment, wherein the organic agent is selected from the group comprising 1,2-ethanedithiol (edt), 1,2- and 1,3-benzenedithiol (bdt), and butylamine.

### EMBODIMENT 38

The detector according to any one of the seven preceding embodiments, wherein the colloidal quantum dots (CQD) are obtainable from a heat treatment of the colloidal film.

### EMBODIMENT 39

The detector according to the preceding embodiment, wherein the heat treatment of the colloidal film comprises drying of the colloidal film in a manner that the continuous phase is removed while the plurality of the quantum dots is maintained.

### EMBODIMENT 40

The detector according to any one of the two preceding embodiments, wherein the heat treatment comprises applying a temperature from 50° C. to 250° C., preferably from 80° C. to 220° C., more preferred from 100° C. to 200° C., preferably in an air atmosphere.

### EMBODIMENT 41

The detector according to any one of the ten preceding embodiments, wherein the quantum dots exhibit a size from 1 nm to 100 nm, preferably from 2 nm to 100 nm, more preferred from 2 nm to 15 nm.

### EMBODIMENT 42

The detector according to any one of the preceding embodiments, wherein the photosensitive layer is provided as a thin film.

### EMBODIMENT 43

The detector according to the preceding embodiment, wherein the thin film exhibits a thickness from 1 nm to 100 nm, preferably from 2 nm to 100 nm, more preferred from 2 nm to 15 nm, wherein, if applicable, the quantum dots exhibits a size below the thickness of the thin film.

### EMBODIMENT 44

The detector according to any one of the preceding embodiments, wherein the photosensitive layer is arranged between a first conductive layer and a second conductive layer in a sandwich structure, wherein at least the first conductive layer exhibits at least partially transparent properties with respect to the incident light beam.

### EMBODIMENT 45

The detector according to the preceding embodiment, wherein the second conductive layer comprises an evaporated metal layer

### EMBODIMENT 45

The detector according to the preceding embodiment, wherein the evaporated metal layer comprises one or more of silver, aluminum, platinum, magnesium, chromium, titanium, or gold.

### EMBODIMENT 47

The detector according to the preceding embodiment, wherein also the second conductive layer exhibits at least partially transparent properties with respect to the incident light beam.

### EMBODIMENT 48

The detector according to the preceding embodiment, wherein the second conductive layer comprises an at least partially transparent semiconducting material.

### EMBODIMENT 49

The detector according to any one of the five preceding embodiments, wherein the second conductive layer comprises an intransparent electrically conducting material.

### EMBODIMENT 50

The detector according to the preceding embodiment, wherein the second conductive layer comprises a layer of graphene.

### EMBODIMENT 51

The detector according to any one of the seven preceding embodiments, wherein the second conductive layer comprises a layer of an electrically conducting polymer.

### EMBODIMENT 52

The detector according to the preceding embodiment, wherein the electrically conducting polymer is selected poly(3,4-ethylenedioxythiophene) (PEDOT) or from a dispersion of PEDOT and a polystyrene sulfonic acid (PEDOT:PSS).

### EMBODIMENT 53

The detector according to any one of the preceding embodiments, further having a blocking layer is further, wherein the blocking layer comprises a thin film of an electrically conducting material.

### EMBODIMENT 54

The detector according to the preceding embodiment, wherein the blocking layer is an n-type semiconductor and comprises one or more of titanium dioxide (TiO₂) or zinc oxide (ZnO), or wherein the blocking layer is a p-type semiconductor comprising molybdenum oxide (MoO₃₋ₓ).

### EMBODIMENT 55

The detector according to any one of the preceding embodiments, further comprising a hole transporting layer, wherein the hole transporting layer comprises a thin film of an electrically conducting material.

### EMBODIMENT 56

The detector according to the preceding embodiment, wherein the hole transporting layer is selected poly(3,4-ethylenedioxythiophene) (PEDOT) or from a dispersion of PEDOT and a polystyrene sulfonic acid (PEDOT:PSS).

### EMBODIMENT 57

The detector according to any one of the preceding embodiments, wherein the transversal optical sensor further has at least one split electrode located at one of the conductive layers, wherein the split electrode has at least two partial electrodes adapted to generate at least one transversal sensor signal.

### EMBODIMENT 58

The detector according to the preceding embodiment, wherein the split electrode has at least four partial electrodes.

### EMBODIMENT 59

The detector according to any one of the two preceding embodiments, wherein a split electrode comprising a metal contact or a graphene contact is arranged on the second conductive layer, wherein the graphene contact exhibits an electrical sheet resistance below 100 Ω/sq, preferably of 1 Ω/sq or below.

### EMBODIMENT 60

The detector according to the preceding embodiment, wherein the metal contact comprises one or more of silver, copper, aluminum, platinum, magnesium, chromium, titanium, or gold.

### EMBODIMENT 61

The detector according to any one of the four preceding embodiments, wherein electrical currents through the partial electrodes are dependent on a position of the light beam in the photosensitive layer.

### EMBODIMENT 62

The detector according to the preceding embodiment, wherein the transversal optical sensor is adapted to generate the transversal sensor signal in accordance with the electrical currents through the partial electrodes.

### EMBODIMENT 63

The detector according to any one of the six preceding embodiments, wherein the detector, preferably the transversal optical sensor and/or the evaluation device, is adapted to derive the information on the transversal position of the object from at least one ratio of the currents through the partial electrodes.

### EMBODIMENT 64

The detector according to any one of the preceding embodiments, wherein the transversal sensor signal is selected from the group consisting of a current and a voltage or any signal derived thereof.

### EMBODIMENT 65

The detector according to any one of the preceding embodiments, furthermore comprising at least one illumination source.

### EMBODIMENT 66

The detector according to the preceding embodiment, wherein the illumination source is selected from: an illumination source, which is at least partly connected to the object and/or is at least partly identical to the object; an illumination source which is designed to at least partly illuminate the object with a primary radiation.

### EMBODIMENT 67

The detector according to the preceding embodiment, wherein the light beam is generated by a reflection of the primary radiation on the object and/or by light emission by the object itself, stimulated by the primary radiation.

### EMBODIMENT 68

The detector according to any one of the preceding embodiments, wherein the detector furthermore has at least one modulation device for modulating the illumination.

### EMBODIMENT 69

The detector according to any one the preceding embodiments, wherein the light beam is one of a non-modulated continuous-wave light beam or a modulated light beam.

### EMBODIMENT 70

The detector according to any one of the preceding embodiments, wherein the evaluation device is further designed to generate at least one item of information on a longitudinal position of the object by evaluating the transversal sensor signal of the transversal optical sensor in a different manner.

### EMBODIMENT 71

The detector according to the preceding embodiment, wherein the different manner comprises treating the transversal sensor signal provided by the transversal optical sensor as at least one longitudinal sensor signal in, wherein the longitudinal sensor signal, given the same total power of the illumination, is dependent on a beam cross-section of the light beam in a sensor region of the transversal optical sensor.

### EMBODIMENT 72

The detector according to any one of the preceding embodiments, further comprising a separate longitudinal optical sensor in addition to the transversal sensor according to any one of the preceding embodiments.

### EMBODIMENT 73

The detector according to any one of the preceding embodiments, wherein the transversal optical sensor and the longitudinal optical sensor are stacked along the optical axis such that the light beam travelling along the optical axis both impinges the transversal optical sensor and the at least two longitudinal optical sensors, wherein the light beam subsequently passes through the transversal optical sensor and the at least two longitudinal optical sensors or vice versa.

### EMBODIMENT 74

The detector according to the preceding embodiment, wherein the light beam passes through the transversal optical sensor before impinging on one of the longitudinal optical sensors.

### EMBODIMENT 75

The detector according to any of the five preceding embodiments, wherein the longitudinal sensor signal is selected from the group consisting of a current and a voltage or any signal derived thereof.

### EMBODIMENT 76

The detector according to any one of the preceding embodiments, wherein the detector further comprises at least one imaging device.

### EMBODIMENT 77

The detector according to the preceding claim, wherein the imaging device is located in a position furthest away from the object.

### EMBODIMENT 78

The detector according to any of the two preceding embodiments, wherein the light beam passes through the at least one transversal optical sensor before illuminating the imaging device.

### EMBODIMENT 79

The detector according to any of the three preceding embodiments, wherein the imaging device comprises a camera.

### EMBODIMENT 80

The detector according to any of the four preceding embodiments, wherein the imaging device comprises at least one of: an inorganic camera; a monochrome camera; a multichrome camera; a full-color camera; a pixelated inorganic chip; a pixelated organic camera; a CCD chip, preferably a multi-color CCD chip or a full-color CCD chip; a CMOS chip; an IR camera; an RGB camera.

### EMBODIMENT 81

An arrangement comprising at least two detectors according to any one of the preceding embodiments.

### EMBODIMENT 82

The arrangement according to the preceding embodiment, wherein the arrangement further comprises at least one illumination source.

### EMBODIMENT 83

A human-machine interface for exchanging at least one item of information between a user and a machine, in particular for inputting control commands, wherein the human-machine interface comprises at least one detector according to any of the preceding embodiments relating to a detector, wherein the human-machine interface is designed to generate at least one item of geometrical information of the user by means of the detector wherein the human-machine interface is designed to assign to the geometrical information at least one item of information, in particular at least one control command.

### EMBODIMENT 84

The human-machine interface according to the preceding embodiment, wherein the at least one item of geometrical information of the user is selected from the group consisting of: a position of a body of the user; a position of at least one body part of the user; an orientation of a body of the user; an orientation of at least one body part of the user.

### EMBODIMENT 85

The human-machine interface according to any of the two preceding embodiments, wherein the human-machine interface further comprises at least one beacon device connectable to the user, wherein the human-machine interface is adapted such that the detector may generate an information on the position of the at least one beacon device.

### EMBODIMENT 86

The human-machine interface according to the preceding embodiment, wherein the beacon device comprises at least one illumination source adapted to generate at least one light beam to be transmitted to the detector.

### EMBODIMENT 87

An entertainment device for carrying out at least one entertainment function, in particular a game, wherein the entertainment device comprises at least one human-machine interface according to any of the preceding embodiments referring to a human-machine interface, wherein the entertainment device is designed to enable at least one item of information to be input by a player by means of the human-machine interface, wherein the entertainment device is designed to vary the entertainment function in accordance with the information.

### EMBODIMENT 88

A tracking system for tracking the position of at least one movable object, the tracking system comprising at least one detector according to any of the preceding embodiments referring to a detector, the tracking system further comprising at least one track controller, wherein the track controller is adapted to track a series of positions of the object, each comprising at least one item of information on a position of the object at a specific point in time.

### EMBODIMENT 89

The tracking system according to the preceding embodiment, wherein the tracking system further comprises at least one beacon device connectable to the object, wherein the tracking system is adapted such that the detector may generate an information on the position of the object of the at least one beacon device.

### EMBODIMENT 90

A scanning system for determining at least one position of at least one object, the scanning system comprising at least one detector according to any of the preceding embodiments relating to a detector, the scanning system further comprising at least one illumination source adapted to emit at least one light beam configured for an illumination of at least one dot located at at least one surface of the at least one object, wherein the scanning system is designed to generate at least one item of information about the distance between the at least one dot and the scanning system by using the at least one detector.

### EMBODIMENT 91

The scanning system according to the preceding embodiment, wherein the illumination source comprises at least one artificial illumination source, in particular at least one laser source and/or at least one incandescent lamp and/or at least one semiconductor light source.

### EMBODIMENT 92

The scanning system according to any one of the two preceding embodiments, wherein the illumination source emits a plurality of individual light beams, in particular an array of light beams exhibiting a respective pitch, in particular a regular pitch.

### EMBODIMENT 93

The scanning system according to any one of the three preceding embodiments, wherein the scanning system comprises at least one housing.

### EMBODIMENT 94

The scanning system according to the preceding embodiment, wherein the at least one item of information about the distance between the at least one dot and the scanning system distance is determined between the at least one dot and a specific point on the housing of the scanning system, in particular a front edge or a back edge of the housing.

### EMBODIMENT 95

The scanning system according to any one of the two preceding embodiments, wherein the housing comprises at least one of a display, a button, a fastening unit, a leveling unit.

### EMBODIMENT 96

A camera for imaging at least one object, the camera comprising at least one detector according to any one of the preceding embodiments referring to a detector.

### EMBODIMENT 97

A method for an optical detection of at least one object, in particular by using a detector according to any of the preceding embodiments relating to a detector, comprising:
generating at least one transversal sensor signal by using at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photosensitive layer embedded between at least two conductive layers, wherein at least one of the conductive layers comprises an at least partially transparent graphene layer on an at least partially transparent substrate allowing the light beam to travel to the photosensitive layer, wherein the transversal optical sensor is further adapted to generate at least one transversal sensor signal indicative of indicative of the transversal position of the light beam in the photosensitive layer; and
generating at least one item of information on a transversal position of the object by evaluating the at least one transversal sensor signal.

### EMBODIMENT 98

The method according to the preceding embodiment, wherein the graphene is placed on the substrate via a deposition method, wherein the deposition method is selected from chemical vapor deposition (CVD), mechanical exfoliation, chemically derived graphene, or growth from silicon carbide.

### EMBODIMENT 99

The detector according to any one of the two preceding embodiments, wherein an inorganic photovoltaic material, an organic photovoltaic material, an inorganic photoconductive material, an organic photoconductive material, or a plurality of colloidal quantum dots (CQD) comprising an inorganic photovoltaic material or an inorganic photoconductive material is provided as the photosensitive layer.

### EMBODIMENT 100

The method according to the preceding embodiment, wherein the colloidal quantum dots (CQD) are obtained from a colloidal film comprising the plurality of the quantum dots.

### EMBODIMENT 101

The method according to the preceding embodiment, wherein the colloidal film is provided in form of sub-micrometer-scale semiconductor crystals dispersed in a continuous phase comprising a medium.

### EMBODIMENT 102

The method according to the preceding embodiment, wherein the colloidal film is provided as a solution of the plurality of the quantum dots in a nonpolar organic solvent.

### EMBODIMENT 103

The method according to the preceding embodiment, wherein the solvent is selected from the group comprising octane, toluene, cyclohexane, chlorobenzene, n-heptane, benzene, dimethylformamide (DMF), acetonitrile, and chloroform,

### EMBODIMENT 104

The method according to the preceding embodiment, wherein the quantum dots are provided in a concentration from 10 mg/ml to 200 mg/ml, preferably from 50 mg/ml to 100 mg/ml, in the organic solvent.

### EMBODIMENT 105

The method according to the preceding embodiment, wherein the colloidal film is deposited onto a first conductive layer.

### EMBODIMENT 106

The method according to any one of the five preceding embodiments, wherein the colloidal film is provided by a deposition method, preferably by a coating method, more preferred by a spin-coating method.

### EMBODIMENT 107

The method according to the preceding embodiment, wherein the colloidal film undergoes a treatment with cross-linking molecules comprising an organic agent, whereby the sub-micrometer-scale semiconductor crystals are, additionally, capped with the cross-linking molecules.

### EMBODIMENT 108

The method according to the preceding embodiment, wherein the organic agent is preferably selected from the group comprising thioles and amines.

### EMBODIMENT 109

The method according to the preceding embodiment, wherein the organic agent is selected from the group comprising 1,2-ethanedithiol (edt), 1,2- and 1,3-benzenedithiol (bdt), and butylamine.

### EMBODIMENT 110

The method according to the preceding embodiment, wherein, after the treatment with the organic agent, the colloidal film is dried in a manner that the continuous phase is removed while the plurality of the quantum dots is maintained.

### EMBODIMENT 111

The method according to the preceding embodiment, wherein the colloidal film is dried at a temperature from 50° C. to 250° C., preferably from 80° C. to 220° C., more preferred from 100° C. to 200° C.

### EMBODIMENT 112

A use of a detector according to any one of the preceding embodiments relating to a detector for a purpose of use selected from the group consisting of: a position measurement in traffic technology; an entertainment application; a security application; a human-machine interface application; a tracking application; a scanning application; a photography application; a cartography application; a mapping application for generating maps of at least one space; a homing or tracking beacon detector for vehicles; a mobile application; a webcam; an audio device; a dolby surround audio system; a computer peripheral device; a gaming application; a camera or video application; a surveillance application; an automotive application; a transport application; a logistics application; a vehicle application; an airplane application; a ship application; a spacecraft application; a robotic application; a medical application; a sports' application; a building application; a construction application; a manufacturing application; a machine vision application; a use in combination with at least one sensing technology selected from time-of-flight detector, radar, lidar, ultrasonic sensors, or interferometry.

### BRIEF DESCRIPTION OF THE FIGURES

Further optional details and features of the invention are evident from the description of preferred exemplary embodiments which follows in conjunction with the dependent claims. In this context, the particular features may be implemented alone or with features in combination. The invention is not restricted to the exemplary embodiments. The exemplary embodiments are shown schematically in the figures. Identical reference numerals in the individual figures refer to identical elements or elements with identical function, or elements which correspond to one another with regard to their functions.

Specifically, in the figures:

FIG. 1 shows an exemplary embodiment of a detector according to the present invention comprising a transversal optical sensor, wherein the transversal optical sensor has a transparent conductive layer comprising graphene;

FIG. 2 shows exemplary embodiments for the setup of the transversal optical sensor, wherein the photosensitive layer comprises an organic photovoltaic material (FIG. 2A), or a plurality of colloidal quantum dots (CQD) comprising an inorganic photoconductive material (FIG. 2B), respectively;

FIG. 3 shows experimental results which demonstrate the applicability of the transversal optical sensor according to FIGS. 1 and 2A as a position sensitive device (FIG. 3A) and a transmission curve of graphene on quartz glass in a partition of the Mid IR spectral range of 1 μm to 3 μm (FIG. 3B); and

FIG. 4 shows an exemplary embodiment of an optical detector, a detector system, a human-machine interface, an entertainment device, a tracking system and a camera according to the present invention.

### EXEMPLARY EMBODIMENTS

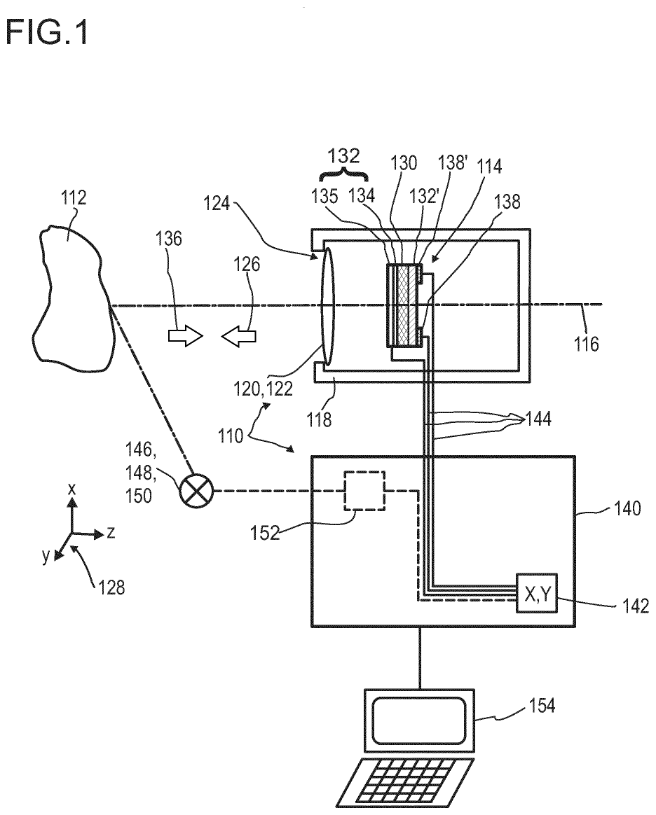

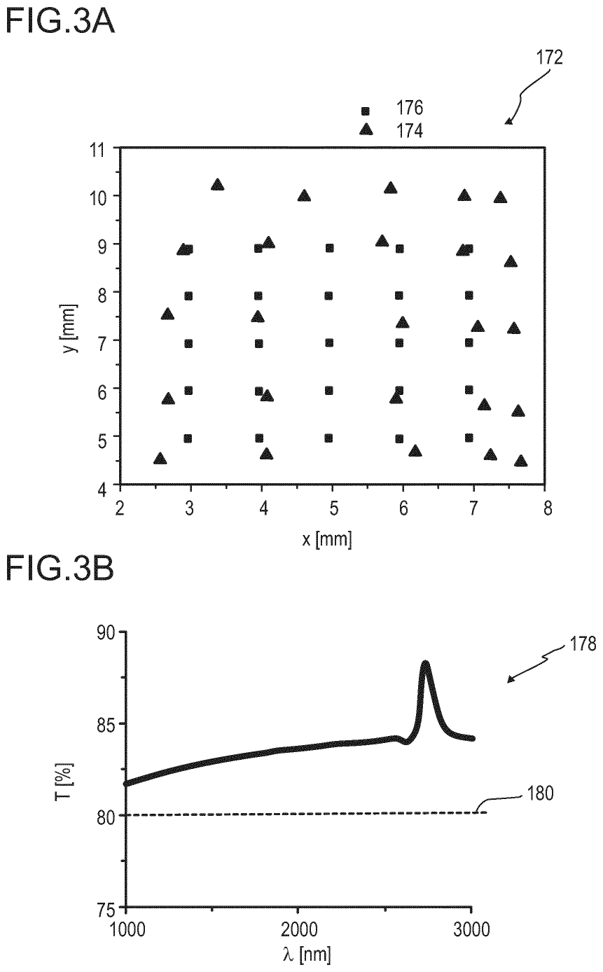

FIG. 1 illustrates, in a highly schematic fashion, an exemplary embodiment of an optical detector 110 according to the present invention, for determining a lateral position of at least one object 112. The optical detector 110 may preferably be adapted to be used as a detector for a partition of the visible spectral range of 380 nm to 760 nm and/or the infrared spectral range of above 760 nm to 1000 μm, particularly for wavelengths in a spectral range of 380 nm to 15 μm, preferably of 380 nm to 3 μm, specifically of 1 μm to 3 μm. As shown below in FIG. 3B in more detail, the graphene layer 134 may, particularly preferred, exhibit a transmission of at least 80% over a wavelength range of 1 μm to 3 μm. However, other embodiments may also be feasible.

The optical detector 110 comprises at least one transversal optical sensor 114, which, in this particular embodiment, may be arranged along an optical axis 116 of the detector 110. Specifically, the optical axis 116 may be an axis of symmetry and/or rotation of the setup of the optical sensors 114. As described elsewhere in this document, the transversal optical sensor 114 may, in a particularly preferred embodiment, concurrently be employed as longitudinal optical sensor adapted for determining a longitudinal position of the at least one object 112. Herein, the transversal optical sensor 114 may be located inside a housing 118 of the detector 110. Further, at least one transfer device 120 may be comprised, preferably a refractive lens 122. An opening 124 in the housing 118, which may, particularly, be located concentrically with regard to the optical axis 116, may preferably define a direction of view 126 of the detector 110. A coordinate system 128 may be defined, in which a direction parallel or antiparallel to the optical axis 116 is defined as a longitudinal direction, whereas directions perpendicular to the optical axis 116 may be defined as transversal directions. In the coordinate system 128 as symbolically depicted in FIG. 1 a longitudinal direction is denoted by z while transversal directions are denoted by x and y, respectively. However, other types of coordinate systems 128 are conceivable.

Further, the transversal optical sensor 114 in this embodiment has a photosensitive layer 130 which is located between two conductive layers i.e. a first conductive layer 132 and a second conductive layer 132′. As described above and/or below in more detail, the photosensitive layer 130 may comprise an inorganic photovoltaic material, an organic photovoltaic material, an inorganic photoconductive material, an organic photoconductive material, or a plurality of quantum dots, in particular, a plurality of colloidal quantum dots (CQD), comprising an inorganic photovoltaic material or an inorganic photoconductive material. Herein, the first conductive layer 132 comprises an at least partially transparent graphene layer 134 deposited on an at least partially transparent substrate 135. Since the first conductive layer 132 is, therefore, at least partially optically transparent, it may, preferably, be located along the optical axis 116 of the optical detector 110 in a fashion that an incident light beam 136 may first traverse the first conductive layer 132 before it may impinge on the photosensitive layer 130.

In order to generate at least one transversal sensor signal which may be indicative of the transversal position of the light beam 136 within the photosensitive layer 130, the transversal optical sensor 114 is equipped with a split electrode which may, in the embodiment as depicted in FIG. 1, be located at the second conductive layer 132′. However, other kinds of setups may also be conceivable. The transversal sensor signal may, preferably, be selected from the group consisting of a current and a voltage or any signal derived thereof. As schematically illustrated in FIG. 1, the split electrode has at least two partial electrodes 138, 138′ which may, in particular, be arranged in a fashion that currents through the partial electrodes 138, 138′ may depend on a position of the light beam 136 within the photosensitive layer 130. This kind of dependency can, in general, be achieved by Ohmic or resistive losses that may occur on a way from a location of a generation and/or modification of electrical charge carriers in the photosensitive layer 130 to the partial electrodes 138, 138′. For this purpose, the graphene layer 134 may exhibit an electrical sheet resistance of 100 Ω/sq to 20000 Ω/sq, preferably of 100 Ω/sq to 10 000 Ω/sq, more preferred 125 of Ω/sq to 1000 Ω/sq, specifically of 150 of Ω/sq to 500 Ω/sq, thus, having a higher electrical resistance compared to the electrical resistance of the photosensitive layer 130 and, concurrently, and a lower electrical resistance compared to the partial electrodes 138, 138′, thus, being adapted for guiding a current always along a path with the lowest Ohmic losses, respectively.

The evaluation device 140 is, generally, designed to generate at least one item of information on a position of the object 112 by evaluating the sensor signal of the transversal optical sensor 114. For this purpose, the evaluation device 140 may comprise one or more electronic devices and/or one or more software components, in order to evaluate the sensor signals, which are symbolically denoted by a transversal evaluation unit 142 (denoted by “xy”). As will be explained below in more detail, the evaluation device 140 may be adapted to determine the at least one item of information on the transversal position of the object 112 by comparing more than one transversal sensor signals of the transversal optical sensor 114.

Herein, the transversal sensor signal may be transmitted to the evaluation device 140 via one or more signal leads 144. By way of example, the signal leads 144 may be provided and/or one or more interfaces, which may be wireless interfaces and/or wire-bound interfaces. Further, the signal leads 144 may comprise one or more drivers and/or one or more measurement devices for generating sensor signals and/or for modifying sensor signals.

The light beam 136 for illumining the sensor region of the transversal optical sensor 114 may be generated by a light-emitting object 112. Alternatively or in addition, the light beam 136 may be generated by a separate illumination source 146, which may include an ambient light source and/or an artificial light source, such as a laser diode 148, being adapted to illuminate the object 112 that the object 112 may be able to reflect at least a part of the light generated by the illumination source 146 in a manner that the light beam 136 may be configured to reach the sensor region of the transversal optical sensor 114, preferably by entering the housing 118 of the optical detector 110 through the opening 124 along the optical axis 116.

In a specific embodiment, the illumination source 146 may be a modulated light source 150, wherein one or more modulation properties of the illumination source 146 may be controlled by at least one optional modulation device 152. Alternatively or in addition, the modulation may be effected in a beam path between the illumination source 146 and the object 112 and/or between the object 112 and the transversal optical sensor 114. Further possibilities may be conceivable. This specific embodiment may allow distinguishing different light beams 136 by taking into account one or more of the modulation properties, in particular the modulation frequency, when evaluating the transversal sensor signal of the transversal optical sensor 114 for determining the at least one item of information on the position of the object 112.

Generally, the evaluation device 140 may be part of a data processing device 154 and/or may comprise one or more data processing devices 154. The evaluation device 140 may be fully or partially integrated into the housing 118 and/or may fully or partially be embodied as a separate device which is electrically connected in a wireless or wire-bound fashion to the transversal optical sensor 114. The evaluation device 140 may further comprise one or more additional components, such as one or more electronic hardware components and/or one or more software components, such as one or more measurement units and/or one or more evaluation units and/or one or more controlling units (not depicted here).

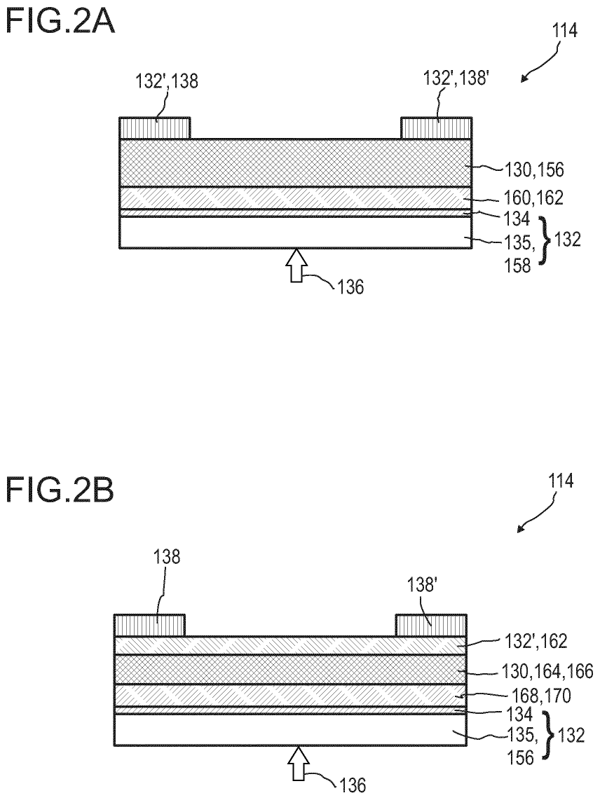

FIG. 2A shows an exemplary embodiment for the setup of the transversal optical sensor 114, wherein, in this particular example, the photosensitive layer 130 may comprise an organic photovoltaic material 156, in particular P3HT:PCBM. As described above in more detail, the organic photovoltaic material 156 comprises poly(3-hexylthiophene-2,5.diyl) (P3HT) as electron donor material and [6,6]-phenyl-C61-butyric acid methyl ester (PCBM) as electron acceptor material, wherein the electron donor material and the electron acceptor material may constitute an interpenetrating network of donor and acceptor domains within the photosensitive layer 130. However, other kinds of substances available for the organic photovoltaic material 156 may also be applicable, in particular, other kinds of electron donor materials and/or electron acceptor materials.

Particularly, in order to achieve the desired high transmission through the first conductive layer 132, the substrate 135 carrying the graphene layer can, as schematically depicted in FIG. 2A, preferably, be selected from quartz glass 158, quartz glass, sapphire, fused silica, silicon, germanium, zinc selenide, zinc sulfide, silicon carbide, aluminum oxide, calcium fluoride, magnesium fluoride, sodium chloride, or potassium bromide.

As a result, the substrate 135 may at least be partially transparent in the visible spectral range and/or in the infrared spectral range, in particular within the same wavelength range of 380 nm to 3 μm in which the graphene, as depicted in FIG. 3B below, exhibits a transmission above 80%. It may be noted that this property turns out to be in contrast to other typically used partially transparent materials, such as indium tin oxide (ITO) or fluorine-doped tin oxide (SnO₂:F; FTO), which exhibit a low transmission within the IR spectral range and may, therefore, not particularly be suited for application in the first conductive layer 132 in the present invention. However, ITO, FTO, or other transparent conducting oxides (TCO) can still be used for the second conductive layer 132′ although, as shown in FIG. 2A, the second conductive layer 132′ may, depending on the path of the light beam 136, also comprise an at least partially intransparent material, preferably, a metal sheet or a low-resistive graphene sheet, wherein the metal sheet may comprise one or more of silver, copper, aluminum, platinum, magnesium, chromium, titanium, or gold, and wherein the low-resistive graphene sheet may have an electrical sheet resistance below 100 Ω/sq, preferably of 1 Ω/sq or below.

As further depicted in FIG. 2A, the transversal optical sensor 114 may, additionally, comprise a hole transporting layer 160. For this purpose, an electrically conducting polymer 162 which may, in particular, be selected from poly(3,4-ethylenedioxythiophene) (PEDOT) or a dispersion of PEDOT and a polystyrene sulfonic acid (PEDOT:PSS) may, preferably, be used. However other kinds of materials for the hole transporting layer 160 may also be feasible. As generally used, the hole transporting layer 160 may, preferably, be adapted to facilitate a transport of the holes on a way through the transversal optical sensor 114. Alternatively, an electron transporting layer (not depicted here) may also be applicable for the present purpose.

As a result, the particular embodiment of the transversal optical sensor 114 as shown in FIG. 2A the may also be denominated as a “photodiode”. In contrast hereto, FIG. 2B illustrates an alternative embodiment of the transversal optical sensor 114 in which the photosensitive layer 130 may be provided in form of a colloidal film 164 which may comprise a plurality of quantum dots 166. As particularly preferred, the quantum dots 166 may comprise nanometer-scale crystals of lead sulfide (PbS) or lead selenide (PbSe), wherein other chalcogenides such as lead sulfoselenide (PbSSe), lead telluride (PbTe), copper indium sulfide (CIS), copper indium gallium selenide (CIGS), copper zinc tin sulfide (CZTS), copper zinc tin selenide (CZTSe), copper-zinc-tin sulfur-selenium (CZTSSe), or cadmium telluride (CdTe) may also be applicable for this purpose. Herein, the nanometer-scale crystals may exhibit a size from 1 nm to 100 nm, preferably from 2 nm to 100 nm, more preferred from 2 nm to 15 nm, while the colloidal film 164 may exhibit a thickness of 1 nm to 100 nm, preferably of 2 nm to 100 nm, more preferred of 2 nm to 15 nm, wherein, however, the sizes of the quantum dots 166 may be selected in a fashion that their size remains below the thickness of the colloidal film 164.

In the embodiment of the transversal optical sensor 114 as schematically illustrated in FIG. 2B, the colloidal film 164 of the sub-micrometer-scale crystals of PbS which constitutes the photosensitive layer 130 is sandwiched between the first conductive layer 132 and the second conductive layer 132′. According to the present invention, the first conductive layer 132 which is traversed by the incident light beam 136 comprises, as described above in more detail, the graphene layer 134 deposited on the at least partially optically transparent substrate 135, preferably, selected from quartz glass 158 or aluminum oxide.

Further, the second conductive layer 132′ may comprise the electrically conducting polymer 162, preferably, poly(3,4-ethylenedioxythiophene) (PEDOT) or a dispersion of PEDOT and a polystyrene sulfonic acid (PEDOT:PSS), which may be deposited onto the colloidal film 164. In order to achieve a good electrical contact to outside electrical connections, a split electrode comprising the at last two evaporated 200 nm silver (Ag) partial electrodes 138, 138′ have been deposited on second conductive layer 132′. Herein, the layer of the electrically conducting polymer 162 may, preferably, exhibit an electrical sheet resistance of 100 Ω/sq to 20 000 Ω/sq, more preferred of 1000 Ω/sq to 15000 Ω/sq, more preferred of 2000 Ω/sq to 10000 Ω/sq. Alternatively, the split electrode may be selected from the group comprising silver, copper, aluminum, platinum, magnesium, chromium, titanium, gold, or low-resistive graphene as described above. Herein, the split electrode may, preferably be arranged as a number of partial electrodes 138, 138′ or in form of a metallic grid.

Further, a hole blocking layer 168 which, preferably, comprises a titanium dioxide (TiO₂) layer 170, may be deposited onto the first conductive layer 132 before the colloidal film 164 may be deposited on top of the hole blocking 168 layer. In the particular embodiment of FIG. 2B, the titanium dioxide layer 170 may be an n-type semiconductor and may comprise titanium dioxide (TiO₂) particles. Alternatively, the hole blocking layer 168 could also comprise zinc oxide (ZnO) or, wherein the blocking layer is a p-type semiconductor, molybdenum oxide (MoO₃). Herein, the hole blocking layer 168 comprising the TiO₂ may, in particular, block a transport of electrons, whereby a recombination between holes and electrons within the hole blocking layer 168 may be excluded.

FIG. 3A shows experimental results which demonstrate the applicability of the transversal optical sensor 114 according to FIGS. 1 and 2A for this purpose. Herein, the transversal optical sensor 114 comprising the setup as schematically depicted in FIG. 2A, has been illuminated by a laser diode 148 emitting a wavelength of 530 nm at an applied current of 1000 mA. Herein, a distance between the laser diode 148 and the transversal optical sensor 114 has been arranged to be about 23 cm while the distance between the laser diode 148 and the transfer device 120 was about 12 cm.

FIG. 3A schematically illustrates a sensor area 172 of the transversal optical sensor 114 in an x-direction and a y-direction, wherein the sensor area 172 as employed here has an active area of 12×12 mm². Herein, for a number of measurement points positions 174 as determined by application of the evaluation device 140 of the transversal optical sensor 114 according to the present invention have been compared with actual positions 176 which have been available by other kinds of methods, such as by employing geometrical considerations in using a known setup of the transversal optical sensor 114.

In order to determine a position 174 of a measurement point by application of transversal optical sensor 114, the following procedure may be used. By way of example (not depicted here), a split electrode comprising four partial electrodes being located on top of the four rims of the second conductive layer 132′ which has a square or a rectangular form is employed. Herein, by generating and/or modifying charge carriers in the photosensitive layer 130, electrode currents may be obtained, which, in each case, may be denoted by i₁, to i₄. As used herein, electrode currents i₁, i₂ may denote electrode currents through the partial electrodes located in y-direction and electrode currents i₃, i₄ may denote electrode currents through the partial electrodes located in x-direction. The electrode currents may be measured by one or more appropriate electrode measurement devices simultaneously or sequentially. By evaluating these electrode currents, the desired x- and y-coordinates of the position 174 of the measurement point under investigation, i.e. x₀ and y₀, may be determined. Thus, the following equations may be used:

$${x}_{0} = f ( \frac{{i}_{3} - {i}_{4}}{{i}_{3} + {i}_{4}} ) and {y}_{0} = f ( \frac{{i}_{1} - {i}_{2}}{{i}_{1} + {i}_{2}} ) .$$

Herein, ƒ might be an arbitrary known function, such as a simple multiplication of the quotient of the currents with a known stretch factor and/or an addition of an offset. Thus, generally, the electrode currents i₁ to i₄ might provide transversal sensor signals generated by the transversal optical sensor 114, whereas the evaluation device 140 might be adapted to generate information on a transversal position, such as at least one x-coordinate and/or at least one y-coordinate, by transforming the transversal sensor signals by using a predetermined or determinable transformation algorithm and/or a known relationship.

The results as shown in FIG. 3A demonstrate that for the number of the measurement points as presented there, the positions 174 as determined by the application of the transversal optical sensor 114 according to the present invention are reasonably comparable with the actual positions 176 acquired by another kinds of method.

As already mentioned above, the transversal sensor 114 according to the present invention may concurrently be employed as a longitudinal optical sensor adapted for determining the z-position. For this purpose, a sum of the electrode currents i₁, i₂ through the partial electrodes located in y-direction and of the electrode currents i₃, i₄ through the partial electrodes located in x-direction may be used in a preferred embodiment, wherein the electrode currents may be measured by one or more appropriate electrode measurement devices simultaneously or sequentially, for determining the z-coordinate. By evaluating these electrode currents, the desired z-coordinate of the position 174 of the measurement point under investigation, i.e. z₀, may be determined by using the following Equation:

z₀=f(i₁+i₂+i₃+i₄)

For further details with respect to evaluating electrode currents in order to obtain the desired z-coordinate, reference may be made to WO 2012/110924 A1 or WO 2014/097181 A1.

FIG. 3B illustrates a transmission curve 178 of the graphene layer 134 on quartz glass 158 over a partition of the Mid IR spectral range from 1 μm to 3 μm after the transmission of the quartz glass 158 has been subtracted. As shown in FIG. 3B, it could be experimentally verified that the graphene layer 134 may exhibit a transmission above a threshold 180 of 80% in a wavelength range of 1 μm to 3 μm. In addition, N.-E. Weber et al., see above, disclose that, depending on details of the preparation, the graphene layer 134 may exhibit a transmission above a threshold 180 of 80% in a wavelength range of 380 nm to 800 nm provided that the graphene layer 134 may exhibit an electrical sheet resistance of at least approx. 2000 Ω/sq. However, further experiments demonstrated that the graphene layer 134 having a lower sheet resistance of 100 Ω/sq to 1000 Ω/sq, preferably of 125 of Ω/sq to 1000 Ω/sq, specifically of 150 of Ω/sq to 500 Ω/sq resulted in an improved frequency response for the optical detector. Consequently, using this setup of the graphene layer 134 on the quartz glass 158 allows providing the first conductive layer 132 in a manner that it actually exhibits the desired high transmission above the threshold 180 of 80% over the partition of the Mid IR spectral range, in particular, of 1 μm to 3 μm.

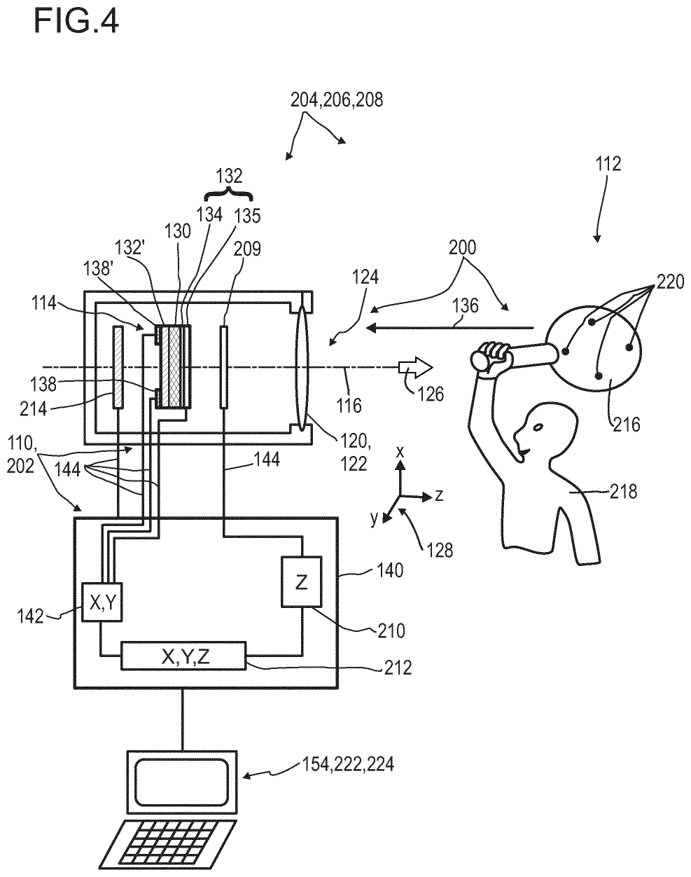

As a further example, FIG. 4 shows an exemplary embodiment of a detector system 200, comprising at least one optical detector 110, wherein the optical detector 110 as disclosed in the embodiments as shown in FIGS. 1 and 2A is used. However, other kinds of optical sensors 110 according to the present invention may also be applicable. Herein, the optical detector 110 may be employed as a camera 202, specifically for 3D imaging, which may be made for acquiring images and/or image sequences, such as digital video clips. Further, FIG. 4 shows an exemplary embodiment of a human-machine interface 204, which comprises the at least one detector 110 and/or the at least one detector system 200, and, further, an exemplary embodiment of an entertainment device 206 comprising the human-machine interface 204. FIG. 4 further shows an embodiment of a tracking system 208 adapted for tracking a position of at least one object 112, which comprises the detector 110 and/or the detector system 200. With regard to the optical detector 110, reference may be made to the full disclosure of this application. Basically, all potential embodiments of the detector 110 may also be embodied in the embodiment shown in FIG. 4.

As described above, the optical detector 110 may comprise a single transversal optical sensor 114 or, as e.g. disclosed in WO 2014/097181 A1, one or more transversal optical sensors 114, particularly, in combination with one or more longitudinal optical sensors 209. In a particularly preferred embodiment, the transversal optical sensor 114 may concurrently be employed as one of the longitudinal optical sensors 209 as described above. Alternatively or in addition, one or more at least partially longitudinal transversal optical sensors 209 may be located on a side of the stack of transversal optical sensors 114 facing towards the object 112. Alternatively or additionally, one or more longitudinal optical sensors 209 may be located on a side of the stack of transversal optical sensors 114 facing away from the object 112. As described in WO 2014/097181 A1, a use of two or, preferably, three longitudinal optical sensors 209 may support the evaluation of the longitudinal sensor signals without any remaining ambiguity. However, embodiments which may only comprise a single transversal optical 114 sensor but no longitudinal optical sensor 209 may still be possible, such as in a case wherein only determining the x- and y-coordinates of the object may be desired. The at least one optional longitudinal optical sensor 209 may further be connected to the evaluation device 140, in particular, by the signal leads 144.

Further, the at least one transfer device 120 may be provided, in particular as the refractive lens 122 or convex mirror. The optical detector 110 may further comprise the at least one housing 118 which, as an example, may encase one or more of components 114, 209.

Further, the evaluation device 140 may fully or partially be integrated into the optical sensors 114, 209 and/or into other components of the optical detector 110. The evaluation device 140 may also be enclosed into housing 118 and/or into a separate housing. The evaluation device 140 may comprise one or more electronic devices and/or one or more software components, in order to evaluate the sensor signals, which are symbolically denoted by the transversal evaluation unit 142 (denoted by “xy”) and a longitudinal evaluation unit 210 (denoted by “z”). By combining results derived by these evolution units 142, 210, a position information 212, preferably a three-dimensional position information, may be generated (denoted by “x, y, z”).

Further, the optical detector 110 and/or to the detector system 200 may comprise an imaging device 214 which may be configured in various ways. Thus, as depicted in FIG. 4, the imaging device 214 can for example be part of the detector 110 within the detector housing 118. Herein, the imaging device signal may be transmitted by one or more imaging device signal leads 144 to the evaluation device 140 of the detector 110. Alternatively, the imaging device 214 may be separately located outside the detector housing 118. The imaging device 214 may be fully or partially transparent or intransparent. The imaging device 214 may be or may comprise an organic imaging device or an inorganic imaging device. Preferably, the imaging device 214 may comprise at least one matrix of pixels, wherein the matrix of pixels may particularly be selected from the group consisting of: an inorganic semiconductor sensor device such as a CCD chip and/or a CMOS chip; an organic semiconductor sensor device.

In the exemplary embodiment as shown in FIG. 4, the object 112 to be detected, as an example, may be designed as an article of sports equipment and/or may form a control element 216, the position and/or orientation of which may be manipulated by a user 218. Thus, generally, in the embodiment shown in FIG. 4 or in any other embodiment of the detector system 200, the human-machine interface 204, the entertainment device 206 or the tracking system 208, the object 112 itself may be part of the named devices and, specifically, may comprise the at least one control element 216, specifically, wherein the at least one control element 216 has one or more beacon devices 220, wherein a position and/or orientation of the control element 216 preferably may be manipulated by user 218. As an example, the object 112 may be or may comprise one or more of a bat, a racket, a club or any other article of sports equipment and/or fake sports equipment. Other types of objects 112 are possible. Further, the user 218 may be considered as the object 112, the position of which shall be detected. As an example, the user 218 may carry one or more of the beacon devices 220 attached directly or indirectly to his or her body.

The optical detector 110 may be adapted to determine at least one item on a transversal position of one or more of the beacon devices 220 and, optionally, at least one item of information regarding a longitudinal position thereof. Particularly, the optical detector 110 may be adapted for identifying colors and/or for imaging the object 112, such as different colors of the object 112, more particularly, the color of the beacon devices 220 which might comprise different colors. The opening 124 in the housing 118, which, preferably, may be located concentrically with regard to the optical axis 116 of the detector 110, may preferably define a direction of a view 126 of the optical detector 110.

The optical detector 110 may be adapted for determining the position of the at least one object 112. Additionally, the optical detector 110, specifically an embodiment including the camera 202, may be adapted for acquiring at least one image of the object 112, preferably a 2D- or a 3D-image. As outlined above, the determination of a position of the object 112 and/or a part thereof by using the optical detector 110 and/or the detector system 200 may be used for providing a human-machine interface 204, in order to provide at least one item of information to a machine 222. In the embodiments schematically depicted in FIG. 4, the machine 222 may be or may comprise at least one computer and/or a computer system comprising the data processing device 154. Other embodiments are feasible. The evaluation device 140 may be a computer and/or may comprise a computer and/or may fully or partially be embodied as a separate device and/or may fully or partially be integrated into the machine 222, particularly the computer. The same holds true for a track controller 224 of the tracking system 208, which may fully or partially form a part of the evaluation device 140 and/or the machine 222.

Similarly, as outlined above, the human-machine interface 204 may form part of the entertainment device 206. Thus, by means of the user 218 functioning as the object 112 and/or by means of the user 218 handling the object 112 and/or the control element 216 functioning as the object 112, the user 218 may input at least one item of information, such as at least one control command, into the machine 222, particularly the computer, thereby varying the entertainment function, such as controlling the course of a computer game.

### LIST OF REFERENCE NUMBERS

110 detector
112 object
114 transversal optical sensor
116 optical axis
118 housing
120 transfer device
122 refractive lens
124 opening
126 direction of view
128 coordinate system
130 photosensitive layer
132, 132′ first conductive layer, second conductive layer
134 graphene layer
135 transparent substrate
136 light beam
138, 138′, 138″ partial electrode
140 evaluation device
142 transversal evaluation unit
144 signal leads
146 illumination source
148 laser diode
150 modulated illumination source
152 modulation device
154 data processing device
156 organic photovoltaic material
158 quartz glass
160 hole transporting layer
162 electrically conducting polymer
164 colloidal film
166 plurality of quantum dots
168 hole blocking layer
170 titanium dioxide layer
172 sensor area
174 determined position
176 actual position
178 sensor area
180 threshold
200 detector system
202 camera
204 human-machine interface
206 entertainment device
208 tracking system
209 longitudinal optical sensor
210 longitudinal evaluation unit
212 position information
214 imaging device
216 control element
218 user
220 beacon device
222 machine
224 track controller

1. A detector for an optical detection of at least one object (112), the detector comprising:
at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photosensitive layer embedded between at least two conductive layers, wherein at least one of the conductive layers comprises an at least partially transparent graphene layer deposited on an at least partially transparent substrate allowing the light beam to travel to the photosensitive layer wherein the transversal optical sensor is further adapted to generate at least one transversal sensor signal indicative of the transversal position of the light beam in the photosensitive layer; and
at least one evaluation device, wherein the evaluation device is designed to generate at least one item of information on a transversal position of the object by evaluating the at least one transversal sensor signal.

2. The detector according to claim 1, wherein the graphene layer (134) exhibits an electrical sheet resistance of 100 Ω/sq to 20 000 Ω/sq.

3. The detector according to claim 1, wherein the graphene layer is at least partially transparent in a partition of a spectral range of 380 m to 1000 μm.

4. The detector according to claim 3, wherein the graphene layer exhibits a transmission above 80% in a spectral range of 1 μm to 3 μm.

5. The detector according to claim 4, wherein the substrate carrying the graphene layer is at least partially transparent in a partition of the visible spectral range and/or in the infrared spectral range.

6. The detector according to claim 5, wherein the substrate comprises a material selected from the group consisting of quartz glass, sapphire, fused silica, silicon, germanium, zinc selenide, zinc sulfide, silicon carbide, aluminum oxide, calcium fluoride, magnesium fluoride, sodium chloride, and potassium bromide.

7. The detector according to claim 1, wherein the photosensitive layer comprises an inorganic photovoltaic material, an organic photovoltaic material, an inorganic photoconductive material, an organic photoconductive material, or a plurality of colloidal quantum dots (CQD) comprising an inorganic photovoltaic material or an inorganic photoconductive material.

8. The detector according to claim 7, wherein the inorganic photovoltaic material is at least one selected from the group consisting of a group II-VI compound, a group III-V compound, a group IV element or compound, a combination, a solid solution thereof, and a doped variant thereof.

9. The detector according to claim 8, wherein the group II-VI compound is a chalcogenide, wherein the chalcogenide is selected from the group consisting of: lead sulfide (PbS), lead selenide (PbSe), lead sulfoselenide (PbSSe), lead telluride (PbTe), copper indium sulfide (CIS), copper indium gallium selenide (CIGS), copper zinc tin sulfide (CZTS), copper zinc tin selenide (CZTSe), copper-zinc-tin sulfur-selenium (CZTSSe), cadmium telluride (CdTe), a solid solution thereof, and a doped variant thereof.

10. The detector according to claim 8, wherein the group IV element or compound is selected from a group consisting of doped diamond (C), doped silicon (Si), silicon carbide (SiC), silicon germanium (SiGe), and doped germanium (Ge), wherein the group IV element or compound is provided as a crystalline material, a microcrystalline material, and an amorphous material.

11. The detector according to claim 7, wherein the organic photovoltaic material comprises at least one electron donor material and at least one electron acceptor material, wherein the electron donor material is selected from the group consisting of poly(3-hexylthiophene-2,5.diyl) (P3HT), poly[3-(4-n-octyl)phenylthiophene] (POPT), poly[3-10-n-octyl-3-phenothiazine-vinylenethiophene-co-2,5-thiophene] (PTZV-PT), poly[4,8-bis[(2-ethylhexyl)oxy] benzo[1,2-b:4,5-b′]dithiophene-2,6-diyl][3-fluoro-2-[(2-ethylhexyl)carbonyl]thieno[3,4-b]thiophenediyl] (PTB7), poly {thiophene-2,5-diyl-alt-[5,6-bis(dodecyloxy)benzo[c][1,2,5]thiadiazole]-4,7-diyl} (PBT-T1), poly[2,6-(4,4-bis-(2-ethylhexyl)-4H-cyclopenta[2,1-b;3,4-b′]dithiophene)-alt-4,7(2,1,3-benzothiadiazole)] (PCPDTBT), poly(5,7-bis(4-decanyl-2-thienyl)-thieno(3,4-b)diathiazolethiophene-2,5) (PDDTT), poly[N-9′-heptadecanyl-2,7-carbazole-alt-5,5-(4′,7′-di-2-thienyl-2′,1′,3′-benzothiadiazole)] (PCDTBT), poly[(4,4′-bis(2-ethylhexyl)dithieno[3,2-b;2′,3′-d]silole)-2,6-diyl-alt-(2,1,3-benzothiadiazole)-4,7-diyl](PSBTBT), poly[3-phenylhydrazone thiophene] (PPHT), poly[2-methoxy-5-(2-ethylhexyl-oxy)-1,4-phenylenevinylene] (MEH-PPV), poly[2-methoxy-5-(2′-ethylhexyloxy)-1,4-phenylene-1,2-ethenylene-2,5-dimethoxy-1,4-phenylene-1,2-ethenylene] (M3EH-PPV), poly[2-methoxy-5-(3′,7′-dimethyloctyloxy)-1,4-phenylenevinylene] (MDMO-PPV), poly[9,9-di-octylfluorene-co-bis-N,N-4-butylphenyl-bis-N,N-phenyl-1,4-phenylenediamine](PFB), or a derivative, a modification, or a mixture thereof, and wherein the electron acceptor material is selected from [6,6]-phenyl-C61-butyric acid methyl ester (PCBM), [6,6]-Phenyl-C71-butyric acid methyl ester (PC70BM), [6,6]-phenyl C84 butyric acid methyl ester (PC84BM), an indene-C60 bisadduct (ICBA), cyano-poly[phenylenevinylene] (CN-PPV), poly[5-(2-(ethylhexyloxy)-2-methoxycyano-terephthalyliden] (MEH-CN-PPV), poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV), poly[1,4-dioctyloxyl-p-2,5-dicyanophenylenevinylene](DOCN-PPV), poly[9,9′-dioctyl-fluoreneco-benzothiadiazole] (PF8BT), a derivative thereof, a modification thereof, and a mixture thereof.

12. The detector according to claim 1, further comprising:
a hole transporting layer, wherein the hole transporting layer comprises an electrically conducting polymer.

13. The detector according to claim 1, wherein the transversal optical sensor further has at least one split electrode located at one of the conductive layers, wherein the split electrode has at least two partial electrodes adapted to generate at least one transversal sensor signal.

14. The detector according to claim 1, wherein electrical currents through the partial electrodes are dependent on a position of the light beam in the photosensitive layer, wherein the transversal optical sensor is adapted to generate the transversal sensor signal in accordance with the electrical currents through the partial electrodes, wherein the detector is adapted to derive the information on the transversal position of the object from at least one ratio of the currents through the partial electrodes.

15. The detector according to claim 1, wherein the evaluation device is further designed to generate at least one item of information on a longitudinal position of the object by evaluating the transversal sensor signal of the longitudinal optical sensor in a different manner.

16. A method for an optical detection of at least one object, the method comprising:
generating at least one transversal sensor signal by using at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photosensitive layer embedded between at least two conductive layers, wherein at least one of the conductive layers comprises an at least partially transparent graphene layer on an at least partially transparent substrate allowing the light beam to travel to the photosensitive layer wherein the transversal optical sensor is further adapted to generate at least one transversal sensor signal indicative of the transversal position of the light beam in the photosensitive layer; and
generating at least one item of information on a transversal position of the object by evaluating the at least one transversal sensor signal.

17. The detector according to claim 1, which is adapted to function as a detector for at least one application selected from the group consisting of a position measurement in traffic technology; an entertainment application; a security application; a human-machine interface application; a tracking application; a scanning application; a photography application; a cartography application; a mapping application for generating maps of at least one space; a homing or tracking beacon detector for vehicles; a mobile application; a webcam; an audio device; a Dolby surround audio system; a computer peripheral device; a gaming application; a camera (202) or video application; a surveillance application; an automotive application; a transport application; a logistics application; a vehicle application; an airplane application; a ship application; a spacecraft application; a robotic application; a medical application; a sports' application; a building application; a construction application; a manufacturing application; a machine vision application; a use in combination with at least one sensing technology selected from time-of-flight detector, radar, Lidar, ultrasonic sensors, and interferometry.
